(19) United States
(12) Patent Application Publication
(10) Pub. No.: US 2025/0159897 A1
(43) Pub. Date: May 15, 2025

(54) SEMICONDUCTOR DEVICE AND DATA STORAGE SYSTEM INCLUDING THE SAME

(71) Applicant: Samsung Electronics Co., Ltd., Suwon-si (KR)

(72) Inventors: Youngji NOH, Suwon-si (KR); Jongho WOO, Suwon-si (KR)

(73) Assignee: Samsung Electronics Co., Ltd., Suwon-si (KR)

(21) Appl. No.: 18/667,010

(22) Filed: May 17, 2024

(30) Foreign Application Priority Data
Nov. 14, 2023 (KR) 10-2023-0157041

(51) Int. Cl. H10B 51/30; H01L 23/00; H01L 25/00; H01L 25/065; H01L 25/18; H10B 51/20; H10B 80/00

(52) U.S. Cl. CPC H10B 51/30; H01L 24/08; H01L 24/80; H01L 25/0657; H01L 25/18; H01L 25/50; H10B 51/20; H10B 80/00; H01L 2224/08145; H01L 2224/80895; H01L 2224/80896; H01L 2924/1431; H01L 2924/1441

(57) ABSTRACT

A semiconductor device includes a stack structure including interlayer insulating layers and gate electrodes stacked in a vertical direction; a plate layer on the stack structure; vertical structures respectively including a back gate electrode penetrating the stack structure and the plate layer in the vertical direction, a channel layer between the back gate electrode and the gate electrodes, and a gate dielectric structure including a ferroelectric layer between the channel layer and gate electrodes; a first horizontal insulating layer on upper surfaces of the plate layer and channel layer; a second horizontal insulating layer on the first horizontal insulating layer and including a material different than the first horizontal insulating layer; and back gate contacts on the respective vertical structures, connected to respective ones of the back gate electrodes, and including a pad region in the second horizontal insulating layer and a via region protruding upwardly from the pad region.

### CROSS-REFERENCE TO RELATED APPLICATION(S)

This application claims the benefit under 35 USC 119 (a) of Korean Patent Application No. 10-2023-0157041 filed on Nov. 14, 2023 in the Korean Intellectual Property Office, the entire disclosure of which is incorporated herein by reference for all purposes.

### BACKGROUND

The present disclosure relates to semiconductor devices, methods of manufacturing the same, and data storage systems including the semiconductor devices.

In electronic systems requiring data storage, semiconductor devices capable of storing high-capacity data are required. Accordingly, ways to increase the data storage capacity of semiconductor devices are being researched. For example, in methods for increasing the data storage capacity of semiconductor devices, a semiconductor device including memory cells arranged three-dimensionally instead of memory cells arranged two-dimensionally has been proposed.

### SUMMARY

Some example embodiments of the inventive concepts provide a semiconductor device including a ferroelectric layer that may store information using a polarization state.

Some example embodiments of the inventive concepts provide a data storage system including the semiconductor device.

Some example embodiments of the inventive concepts provide a method of forming the semiconductor device.

Some example embodiments of the inventive concepts provide a semiconductor device that includes a stack structure including interlayer insulating layers and gate electrodes alternately stacked in a vertical direction; a plate layer on the stack structure; vertical structures respectively including a back gate electrode penetrating through the stack structure and the plate layer in the vertical direction, a channel layer between the back gate electrode and the gate electrode, and a gate dielectric structure including a ferroelectric layer between the channel layer and the gate electrodes; a first horizontal insulating layer on upper surfaces of the plate layer and the channel layer; a second horizontal insulating layer on the first horizontal insulating layer, the second horizontal layer including a material different than a material of the first horizontal insulating layer; and back gate contacts respectively on the vertical structures, the back gate contacts being electrically connected to respective ones of the back gate electrodes of the vertical structures, and the back gate contacts including a pad region in the second horizontal insulating layer and a via region protruding upwardly from the pad region.

Some example embodiments of the inventive concepts further provide a semiconductor device that includes a first semiconductor structure including a first substrate, circuits on the first substrate, a lower interconnection structure electrically connected to the circuits, and a lower bonding structure connected to the lower interconnection structure; and a second semiconductor structure including a second substrate on the first semiconductor structure, a stack structure including interlayer insulating layers and gate electrodes stacked in a vertical direction perpendicular to a lower surface of the second substrate, vertical structures respectively including a back gate electrode penetrating through the stack structure and the second substrate in the vertical direction, the vertical structures including a channel layer between the back gate electrode and the gate electrodes, an upper interconnection structure below the vertical structures, and an upper bonding structure connected to the upper interconnection structure and bonded to the lower bonding structure. The second semiconductor structure further includes a first horizontal insulating layer on the second substrate; a second horizontal insulating layer on the first horizontal insulating layer and including a material different than a material of the first horizontal insulating layer; and back gate contacts respectively on the vertical structures, the back gate contacts being electrically connected to respective ones of the back gate electrodes of the vertical structures, and the back gate contacts including a pad region in the second horizontal insulating layer and a via region protruding upwardly from the pad region.

Some example embodiments of the inventive concepts still further provide a data storage system that includes a semiconductor device including an input/output pad; and a controller electrically connected to the semiconductor device through the input/output pad and controlling the semiconductor device. The semiconductor device includes a stack structure including interlayer insulating layers and gate electrodes stacked in a vertical direction; a plate layer on the stack structure; vertical structures respectively including a back gate electrode penetrating through the stack structure and the plate layer in the vertical direction, a channel layer between the back gate electrode and the gate electrodes, and a gate dielectric structure including a ferroelectric layer between the channel layer and the gate electrodes; a first horizontal insulating layer on upper surfaces of the plate layer and the channel layer; a second horizontal insulating layer on the first horizontal insulating layer, the second horizontal layer including a material different than a material of the first horizontal insulating layer; and back gate contacts respectively on the vertical structures, the back gate contacts being electrically connected to respective ones of the back gate electrodes of the vertical structures, and the back gate contacts including a pad region in the second horizontal insulating layer, a via region protruding upwardly from the pad region and a protrusion protruding downward from the pad region toward an upper surface of the respective ones of the back gate electrodes and contacting the respective ones of the back gate electrodes.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a circuit diagram illustrating a unit memory cell of a semiconductor device according to some example embodiments of the inventive concepts;

FIGS. 2 and 3 are plan and cross-sectional views illustrating a cell array of a semiconductor device according to some example embodiments of the inventive concepts;

FIGS. 4A and 4B are partially enlarged cross-sectional views of a semiconductor device according to some example embodiments of the inventive concepts;

FIGS. 5A and 5B are diagrams illustrating a program operation and an erase operation of a semiconductor device according to some example embodiments of the inventive concepts;

FIGS. 6, 7, 8, 9 and 10 are partially enlarged cross-sectional views conceptually illustrating modified examples of semiconductor devices according to some example embodiments of the inventive concepts;

FIGS. 11A, 11B, 11C, 11D, 11E, 11F, 11G, 11H, 11I, 11J, 11K, 11L and 11M are diagrams conceptually illustrating an example of a method of forming a semiconductor device according to an some example embodiments of the inventive concepts;

FIG. 12 is a diagram schematically illustrating a data storage system including a semiconductor device according to some example embodiments of the inventive concepts;

FIG. 13 is a perspective view schematically illustrating a data storage system including a semiconductor device according to some example embodiments of the inventive concepts; and

FIG. 14 is a cross-sectional view schematically illustrating a data storage system including a semiconductor device according to some example embodiments of the inventive concepts.

### DETAILED DESCRIPTION

Hereinafter, terms such as “upper”, “middle”, “intermediate”, “lower” and the like are replaced by other terms such as “first”, “second” and “third”, and may also be used to describe components of the specification. Terms such as “first,” “second,” “third” and the like may be used to describe various components, but the components are not limited by the above terms, and the “first component” may be referred to as the “second component.”

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

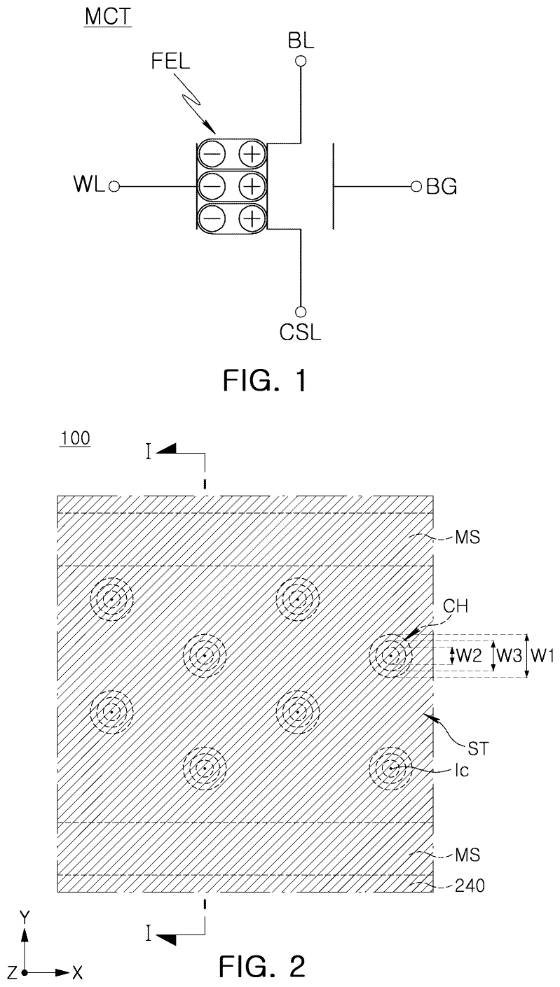

With reference to FIGS. 1 to 4B, a semiconductor device according to an some example embodiments will be described. FIG. 1 is a circuit diagram illustrating a unit memory cell of a semiconductor device according to an some example embodiments.

Referring to FIG. 1, each memory cell MCT may be controlled by a word line WL and a back gate line BG. Each memory cell MCT may include a gate electrode, a source electrode, a drain electrode, a channel between the source electrode and the drain electrode, and a back gate electrode. The gate electrode of each memory cell MCT may be connected to the word line WL, and the back gate electrode may be connected to the back gate line BG. A bit line BL may be connected to the drain electrode, and a common source line CSL may be connected to the source electrode. Each memory cell MCT may include a ferroelectric film FEL as a memory film (or data storage film) between the channel region and the back gate electrode.

The ferroelectric film FEL may have a spontaneous dipole (electric dipole), for example, spontaneous polarization, as the charge distribution within each memory cell MCT is non-centrosymmetric. A ferroelectric film FEL has remnant polarization due to a dipole even in the absence of an external electric field. The direction of polarization may be switched by an external electric field.

In detail, the ferroelectric film FEL may have a positive or negative polarization state, and the polarization state may vary depending on the electric field applied to the ferroelectric film FEL during the program operation. The polarization state of the ferroelectric film FEL may be maintained even when power is turned off, so the semiconductor memory device may operate as a non-volatile memory device. In some example embodiments, the polarization state of the ferroelectric film FEL may be determined by the voltage difference between the channel region and the gate electrode.

For example, during a program operation, the channel region in the memory cell MCT may be depleted by the program voltage applied to the gate electrode, and the polarity of the ferroelectric film FEL may change depending on the voltage difference between the program voltage applied to the gate electrode and the channel region. The voltage difference between the program voltage and the channel region may be a minimum voltage or more required to change the polarization of the ferroelectric film FEL.

When reading data from a memory cell MCT, by measuring the current flowing through the channel area of the selected memory cell MCT, data stored in the memory cell MCT may be read. During the program operation, a voltage (pass voltage) at the same level as the voltage (pass voltage) of the gate electrode of the unselected memory cell MCT is applied to the back gate electrode. The influence of the polarization state caused by the high program voltage of the neighboring gate electrode may be significantly reduced.

The semiconductor device of the present disclosure may be implemented as a vertical structure CH in which the memory cell MCT of FIG. 1 forms a string shape.

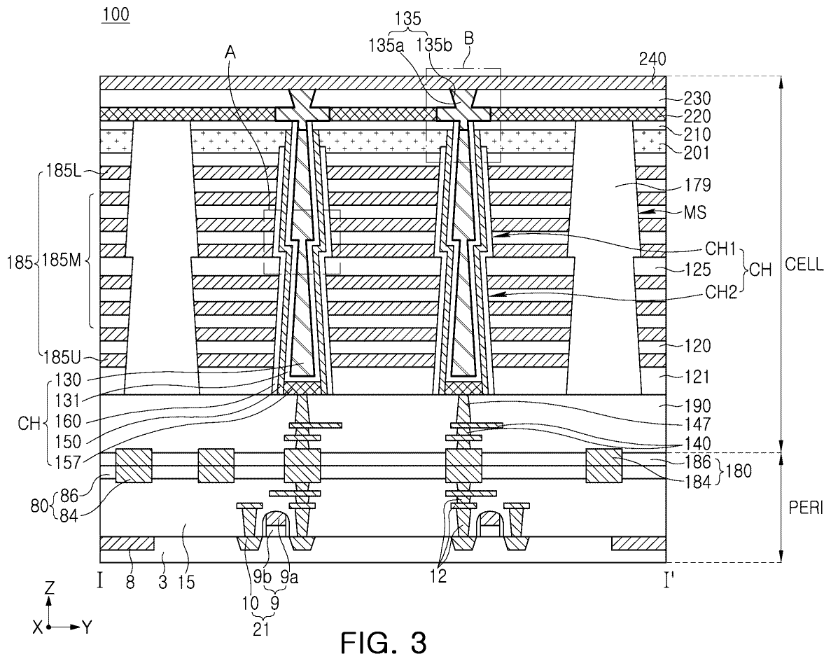

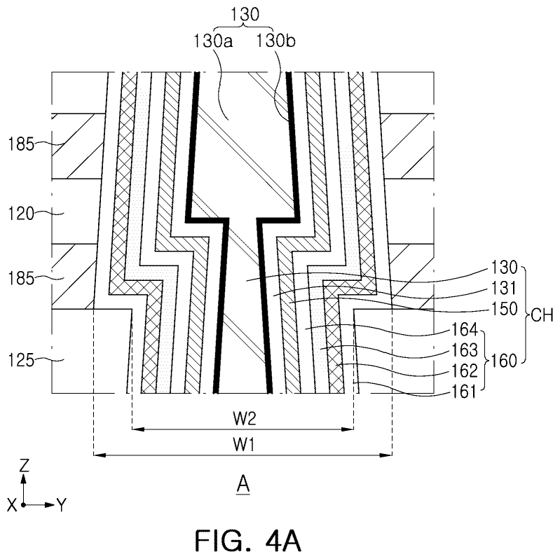

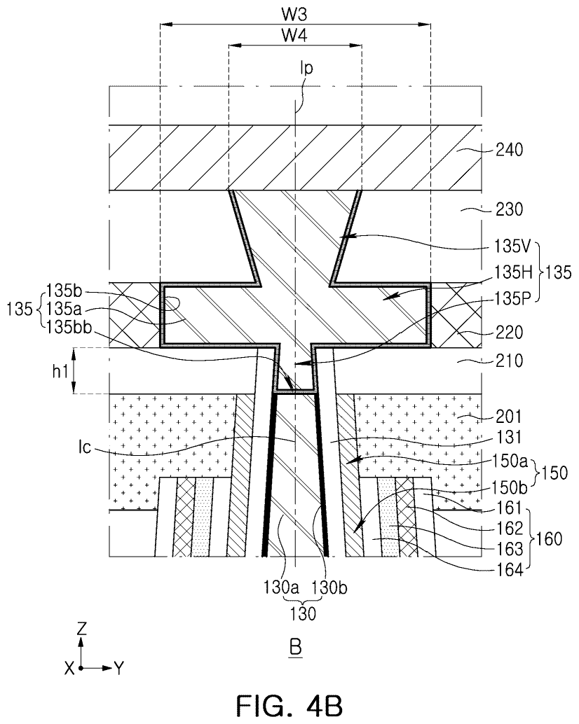

FIGS. 2 and 3 are plan and cross-sectional views illustrating a cell array of a semiconductor device according to some example embodiments, and FIGS. 4A and 4B are partially enlarged cross-sectional views illustrating a semiconductor device according to some example embodiments.

Referring to FIGS. 2 to 4B, the semiconductor device 100 according to some example embodiments may include a first region CELL and a second region PERI. The first region CELL may vertically overlap the second region PERI.

In some example embodiments, the first region CELL may be a memory area where three-dimensionally arranged memory cells are placed, and the second region PERI may be a peripheral circuit area.

In some example embodiments, the first region CELL may be referred to as a memory chip structure or a first chip structure, and the second region PERI may be referred to as a peripheral circuit structure or a second chip structure.

The second region PERI may include a first substrate 3, circuit elements 21 on the first substrate 3, a lower interconnection structure 12, a lower bonding structure 80, and a lower capping layer 15.

The first substrate 3 may include a semiconductor material, such as a group IV semiconductor, a group III-V compound semiconductor, or a group II-VI compound semiconductor. The first substrate 3 may be provided as a bulk wafer or an epitaxial layer. An active area may be defined in the first substrate 3 by device isolation layers. Source/drain regions 10 containing impurities may be disposed in a portion of the active region.

The circuit elements 21 may include transistors. Each circuit element 21 may include a circuit gate dielectric layer 9b, a circuit gate electrode 9a, and a source/drain region 10. The source/drain regions 10 containing impurities may be disposed in the first substrate 3 on both sides of the circuit gate electrode 9a. Spacer layers may be disposed on both sides of the circuit gate electrode 9a. The circuit gate dielectric layer 9b may include silicon oxide, silicon nitride, or a high-k material. The circuit gate electrode 9a may include at least one of titanium nitride (TiN), tantalum nitride (TaN), tungsten nitride (WN), titanium silicon nitride (TiSiN), tantalum silicon nitride (TaSiN), and tungsten silicon nitride (WSiN), tungsten (W), copper (Cu), aluminum (Al), molybdenum (Mo), and ruthenium (Ru). The circuit gate electrode 9a may include a semiconductor layer, for example a doped polycrystalline silicon layer. According to some example embodiments, the circuit gate electrode 9a may be composed of two or more multiple layers.

The lower interconnection structure 12 may be electrically connected to the circuit gate electrodes 9a and the source/drain regions 10 of the circuit elements 21. The lower interconnection structure 12 may include lower contact plugs in the shape of a cylinder or truncated cone and lower interconnection lines in at least one area of which are in the form of a line. Some of the lower contact plugs may be connected to the source/drain regions 10, and, although not illustrated, other some of the lower contact plugs may be connected to the gate electrodes 9a. The lower contact plugs may electrically connect the lower interconnection lines 12 disposed at different levels from the upper surface of the first substrate 3 to each other. The lower interconnection structure 12 may include a conductive material, for example, tungsten (W), copper (Cu), aluminum (Al), or the like. Each component may further include a diffusion barrier comprising at least one of titanium (Ti), titanium nitride (TiN), tantalum (Ta), tantalum nitride (TaN), and tungsten nitride (WN). According to some example embodiments, the number of layers and arrangement form of the lower contact plugs and lower interconnection lines constituting the lower interconnection structure 12 may be changed in various manners.

The lower bonding structure 80 may be connected to the lower interconnection structure 12. The lower bonding structure 80 may include a lower bonding via, a lower bonding pad 84, and a lower bonding insulating layer 86. The lower bonding via may be connected to the lower interconnection structure 12. The lower bonding pad 84 may be connected to the lower bonding via. The lower bonding via and lower bonding pad 84 may include a conductive material, for example, tungsten (W), copper (Cu), aluminum (Al), or the like. Each component may further include a diffusion barrier. The lower bonding insulating layer 86 may also function as a diffusion barrier for the lower bonding pad 84, and may include at least one of SiCN, SiO, SiN, SiOC, SiON, and SiOCN. The lower bonding insulating layer 86 may have a thickness smaller than that of the lower bonding pad 84, but is not limited thereto. The lower bonding structure 80 may be bonded or connected to the upper bonding structure 180 through direct contact through hybrid bonding. For example, the lower bonding pad 84 may be in contact with the upper bonding pad 184 and bonded through copper-to-copper bonding, and the lower bonding insulating layer 86 may be in contact with the upper bonding insulating layer 186 and bonded thereto by dielectric-to-dielectric bonding. The lower bonding structure 80, together with the upper bonding structure 180, may provide an electrical connection path between the second region PERI and the first region CELL.

The lower capping layer 15 may be disposed on the first substrate 3 to cover the circuit elements 21 and the lower interconnection structure 12. The lower capping layer 15 may include a plurality of insulating layers. The lower capping layer 15 may include an insulating material, for example, silicon oxide, silicon nitride, silicon oxynitride, or silicon oxycarbide.

The first region CELL may include a second substrate 201, gate electrodes 185 stacked under the second substrate 201, a separation region MS extending through the stack structure ST of the gate electrodes 185, a stack structure ST and a vertical structure CH penetrating through the stack structure ST and the second substrate 201, contact plugs 147 for electrical connection with the second region PERI, an upper interconnection structure 140 below the stack structure ST, and an upper bonding structure 180 connected to the upper interconnection structure 140.

The first region CELL may further include interlayer insulating layers 120 alternately stacked with gate electrodes 185 under the second substrate 201, a first horizontal insulating layer 210 and a second horizontal insulating layer 220 on the second substrate 201 and an upper insulating layer 230 covering the stack structure ST, back gate contacts 135 including a via region, and an upper interconnection 240 covering back gate contacts 135.

The second substrate 201 may include a semiconductor material, such as a group IV semiconductor, a group III-V compound semiconductor, or a group II-VI compound semiconductor. For example, the group IV semiconductor may include silicon (Si), germanium (Ge), or silicon-germanium (SiGe). The second substrate 201 may function as a common source line of the semiconductor device 100. For example, the second substrate 201 may include a doped polysilicon layer having an N-type conductivity type. The second substrate 201 may also be referred to as a source layer, a source conductive layer, a semiconductor plate layer, or a plate layer. The channel layer 150 may be in contact with the second substrate 201. According to some example embodiments, the second substrate 201 may be formed to have a desired (and/or alternatively predetermined) thickness to be penetrated by the vertical structures CH. For example, the second substrate 201 may have an upper surface at the same level as the upper surface of the channel layer 150 of the vertical structures CH.

The stack structure ST may include interlayer insulating layers 120 and gate electrodes 185 that are alternately and repeatedly stacked in the vertical direction Z. The stack structure ST may vertically overlap the second region PERI, which may be a peripheral circuit structure.

The gate electrodes 185 may be vertically spaced apart and stacked under the second substrate 201 to form a stack structure. The gate electrodes 185 may be disposed between the second substrate 201 and the upper interconnection structure 140. The gate electrodes 185 may sequentially include electrodes forming a ground selection transistor, memory cells, and a string selection transistor from the second substrate 201. The number of gate electrodes 185 forming the memory cells may be determined according to the storage capacity of the semiconductor device 100. In some example embodiments, the number of gate electrodes 185 forming the string selection transistor and the ground selection transistor may be one or two or more, respectively, and may have the same or different structure as the gate electrodes 185 of the memory cells. The gate electrodes 185 may further include a gate electrode 185 disposed below the gate electrode 185 forming the string selection transistor and above the gate electrode 185 forming the ground selection transistor and forming an erase transistor used in an erase operation using GIDL (Gate Induced Drain Leakage) phenomenon.

The gate electrodes 185 may form a lower gate stacked group and an upper gate stacked group on the lower gate stacked group. An intermediate interlayer insulating layer 125 disposed between the lower gate stacking group and the upper gate stacking group may have a relatively thick thickness, but is not limited thereto.

The gate electrodes 185 may include lower gate electrodes 185L, middle gate electrodes 185M, and upper gate electrodes 185U.

The middle gate electrodes 185M may form word lines. The middle gate electrodes 185M may also be referred to as word lines.

In an example, at least one of the lower gate electrodes 185L may be a lower selection gate electrode, and at least one of the upper gate electrodes 185U may be an upper selection gate electrode. For example, at least one of the lower gate electrodes 185L may be a ground selection gate electrode, and at least one of the upper gate electrodes 185U may be a string selection gate electrode.

In an example, at least one of the lower gate electrodes 185L and the upper gate electrodes 185U may be an erase control gate electrode that may be used for an erase operation by generating a GIDL current due to the GIDL phenomenon in a NAND flash memory device.

The interlayer insulating layers 120 may include an insulating material such as silicon oxide. Among the interlayer insulating layers 120, the highest interlayer insulating layer 121 may be thicker than the remaining interlayer insulating layers 120, like the intermediate interlayer insulating layer 125.

The gate electrodes 185 may include a conductive material. For example, each of the gate electrodes 185 may be polysilicon, W, Ru, Mo, Nb, Ni, Co, Ti, Ta, TiN, TaN, WN, NbN, TiAl, TiAlN, TiSi, TiSiN, TaSi., TaSiN, RuTiN, NiSi, CoSi, or combinations thereof, but is not limited thereto. For example, each of the gate electrodes 185 may include a single layer or multiple layers of the materials described above.

The separation regions MS may be arranged to extend in the Z-direction through the gate electrodes 185. The separation regions MS may penetrate the entire gate electrodes 185 stacked below the second substrate 201 and be connected to the second substrate 201. A separation insulating layer 179 may be disposed in the separation regions MS. The separation region MS may have a shape whose width decreases toward the second substrate 201 due to the high aspect ratio. The separation region MS may extend in the X-direction to separate the gate electrodes 185 from each other in the Y-direction. According to some example embodiments, a conductive layer may be further disposed in the separation insulating layer 179 in the separation regions MS. The isolation insulating layer 179 may include an insulating material such as silicon oxide or silicon nitride, for example, silicon oxide, silicon nitride, or silicon oxynitride.

The vertical structures CH may be arranged to continuously penetrate the stack structure ST and the second substrate 201. The vertical structures CH respectively form one memory cell string and may be arranged to be spaced apart from each other in rows and columns in the first region CELL. The vertical structures CH may be arranged to form a grid pattern in the X-Y plane or may be arranged in a zigzag fashion in one direction. The vertical structures CH may penetrate the gate electrodes 185 and extend in a vertical direction, for example, the Z-direction, perpendicular to the lower surface of the second substrate 201, and have a pillar shape and may have inclined sides whose width becomes narrower as it approaches the second substrate 201 depending on the aspect ratio. The width W2 of the upper surface of the vertical structures CH may be smaller than the width W1 of the lower surface of the vertical structures CH.

Each of the vertical structures CH may have a shape in which lower and upper vertical structures CH1 and CH2 respectively penetrating through the lower gate stacked group and the upper gate stacked group of the gate electrodes 185 are connected, and may have a bent portion caused by a difference or change in the width W1 of the lower surface of the upper vertical structure CH2 and the width W2 of the upper surface of the lower vertical structure CH1 in the connection area.

Each of the vertical structures CH may include a back gate electrode 130, a first insulating layer 131, a channel layer 150, and a gate dielectric structure 160.

The back gate electrode BG 130 is located at the center of the hole filled by the vertical structure CH, and may have a pillar shape extending in the Z-direction. Alternatively, the back gate electrode 130 may have a U-shaped cross section and the interior thereof may be filled with an insulating material. The back gate electrode 130 penetrates the second substrate 201 and may be spaced apart from the second substrate 201, and may be connected to the back gate line of the upper interconnection 240 by the upper back gate contact 135. The level of the upper surface of the back gate electrode 130 and the level of the second substrate 201 may be the same, but are not limited thereto.

The back gate electrode 130 may include a barrier layer 130b on the side and lower surfaces, and the barrier layer 130b is a diffusion barrier, and may include, as the conductive material layer 130a therein, at least one selected from doped semiconductor (for example, doped silicon, etc.), metal (for example, tungsten, copper, aluminum, etc.), conductive metal nitride (for example, titanium nitride, tantalum nitride, etc.), or transition metals (for example, titanium, tantalum, etc.), or the like. The barrier layer 130b may include at least one of titanium (Ti), titanium nitride (TiN), tantalum (Ta), tantalum nitride (TaN), and tungsten nitride (WN).

The vertical structures CH may further include a first insulating layer 131 surrounding the back gate electrode 130. The first insulating layer 131 may include an insulating material such as silicon oxide, and may have a U-shaped cross section to cover the side and lower surfaces of the back gate electrode 130.

The upper surface of the first insulating layer 131 may be located at a higher level than the upper surface of the second substrate 201, and may protrude above the second substrate 201. The upper surface of the second insulating layer 131 may be located at a higher level than the upper surface of the back gate electrode 130, and may be located at a level higher than the upper surface of the channel layer 150. Therefore, the first insulating layer 131 may form an uppermost end of the vertical structure CH, and by the height of the upper surface protruding from the channel layer 150, the back gate electrode 130, and the second substrate 201, a short circuit may be limited and/or prevented by separating the back gate contact 135 connected to the back gate electrode 130 from the second substrate 201 and the channel layer 150.

The channel layer 150 may be connected between the lower vertical structure CH1 and the upper vertical structure CH2. The channel layer 150 may include a protrusion 150a and a non-protrusion 150b of the channel layer 150. The non-protruding portion 150b is an area that occupies most of the channel layer 150 and may be defined as an area covered by the gate dielectric structure 160 from the side.

The non-protruding portion 150b may be disposed in an area penetrating most of the stack structure ST, but may also be disposed partially within the second substrate 201. The protrusion 150a extends from the non-protrusion 150b and may be defined as an area where the gate dielectric structure 160 is removed to directly contact the second substrate 201.

The protrusion 150a is disposed on top of the non-protrusion 150b and on the channel layer 150, so that the upper surface of the protrusion 150a may be the upper surface of the channel layer 150.

The upper surface of the protrusion 150a may be at a lower level than the upper surface of the first insulating layer 131 and may be coplanar with the upper surface of the second substrate 201. The upper surface of the channel layer 150 may contact the first horizontal insulating layer 210 disposed on the second substrate 201.

Accordingly, the upper part of the protrusion 150a of the channel layer 150 is spaced apart from the upper back gate contact 135 by the first horizontal insulating layer 210 and the first insulating layer 131, and may be spaced apart from the internal back gate electrode 130. The channel layer 150 may be formed in an annular shape surrounding the internal first insulating layer 131.

The channel layer 150 may include a semiconductor material such as polycrystalline silicon or single crystalline silicon, and the semiconductor material may be an undoped material or a material containing p-type or n-type impurities. The channel layer 150 may include a semiconductor material. For example, the channel layer 150 may include at least one of doped silicon, undoped silicon, doped polysilicon, undoped polysilicon, or an oxide semiconductor. The oxide semiconductor may be indium gallium zinc oxide (IGZO), but some example embodiments are not limited thereto. For example, the oxide semiconductor may contain at least one of Indium Tungsten Oxide (ITO), Indium Tin Gallium Oxide (ITGO), Indium Aluminum Zinc Oxide (IAZO), Indium Gallium Oxide (IGO), Indium Tin Zinc Oxide (ITZO), zinc tin oxide (ZTO), indium zinc oxide (IZO), zinc oxide (ZnO), indium gallium silicon oxide (IGSO), indium oxide (InO), tin oxide (SnO), titanium oxide (TiO), zinc oxynitride (ZnON), magnesium zinc oxide (MgZnO), indium Zinc Oxide (InZnO), Indium Gallium Zinc Oxide (InGaZnO), Zirconium Indium Zinc Oxide (ZrInZnO), Hafnium Indium Zinc Oxide (HfInZnO), Tin Indium Zinc Oxide (SnInZnO), Aluminum Tin Indium Zinc Oxide (AlSnInZnO), Silicon Indium Zinc oxide (SiInZnO), zinc tin oxide (ZnSnO), aluminum zinc tin oxide (AlZnSnO), gallium zinc tin oxide (GaZnSnO), zirconium zinc tin oxide (ZrZnSnO), and indium gallium silicon oxide (InGaSiO).

The vertical structures ST may further include a pad pattern 157. The pad pattern 157 may be disposed on the lower surface of the first insulating layer 131 and may be connected to the channel layer 150. The pad pattern 157 may be disposed at a lower level than the upper gate electrode 185U at the lowest level, among the gate electrodes 185. The pad pattern 157 may include a conductive material, for example, doped polysilicon having an N-type conductivity type.

The vertical structures CH may further include a gate dielectric structure 160 on the outer surface of the channel layer 150.

The gate dielectric structure 160 may include a plurality of stack structures.

The gate dielectric structure 160 may further include an interface insulating layer 164 on the outer surface of the channel layer 150, a second information storage layer 163 on the interface insulating layer 164, a first information storage layer 162 on the second information storage layer 163, and a second insulating layer 161 on the first information storage layer 162.

The interface insulating layer 164 may include at least one of silicon oxide, SiON, AlON, and high-K dielectric. The high dielectric may be a dielectric having a higher dielectric constant than that of silicon oxide.

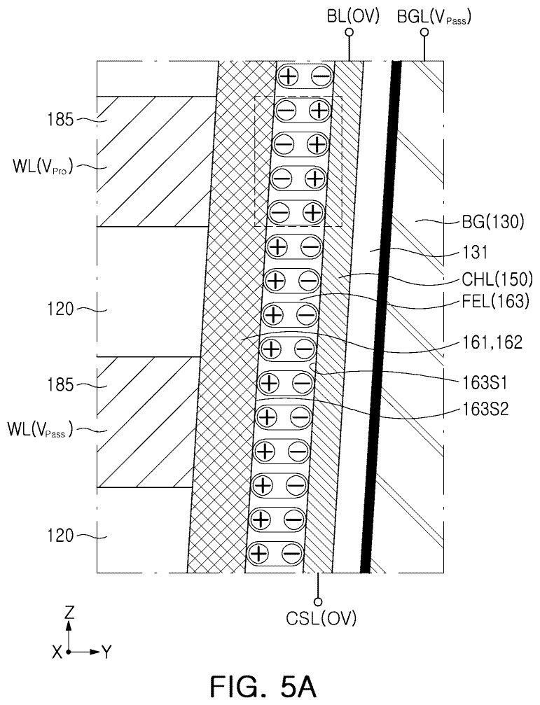

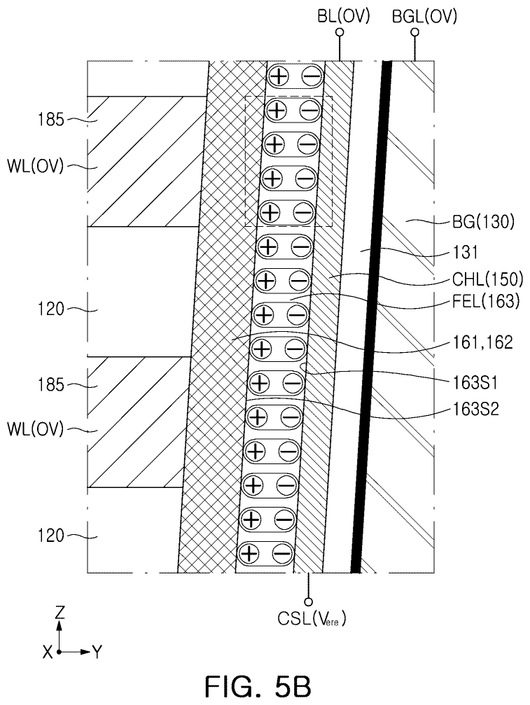

The second information storage layer 163 may be disposed between the first information storage layer 162 and the channel layer 150. The second information storage layer 163 may have a first side 163S1 and a second side 163S2 facing each other (e.g., see FIG. 5A). The first side 163S1 may face the channel layer 150, and the second side 163S2 may face the first information storage layer 162.

The material of the first information storage layer 162 may be different from the material of the second information storage layer 163.

The first information storage layer 162 may be a charge trap layer capable of storing data using a charge trap. The first information storage layer 162 may include at least one of SiO, SiN, SION, SiO/SiN, SiO/SION, SiO/AlO, SiO/HfO, SiO/SiN/SiO or SiO/nano-crystals that may store data using a charge trap. For example, expressions such as SiO/SiN may mean a stack structure of a SiN material layer and a SiO material layer. The first information storage layer 162 may include at least one of Si(O)N, (Hf, Zr, Al, C, N, Gd, Y, Ti, La, Ta)-doped Si(O)N, or HfO₂.

The second information storage layer 163 may be a ferroelectric layer. The second information storage layer 163, which may be a ferroelectric layer, may have polarization characteristics depending on the electric field, and may have remnant polarization due to a dipole even in the absence of an external electric field. The second information storage layer 163 may record data using the polarization state within the ferroelectric layer. The second information storage layer 163 facing the middle gate electrodes 185M, which may be word lines, may be areas that store information using a polarization state.

The second information storage layer 163 may be a ferroelectric layer including an Hf-based compound, a Zr-based compound, and/or an Hf—Zr-based compound. For example, the Hf-based compound may be a ferroelectric material based on HfO, Zr-based compounds may include ZrO-based ferroelectric materials, and Hf—Zr-based compounds may include HZO (hafnium zirconium oxide)-based ferroelectric materials.

The second information storage layer 163 may include ferroelectric materials doped with at least one of impurities such as Zr, C, Si, Mg, Al, Y, N, Ge, Sn, Gd, La, Sc, and Sr. For example, the ferroelectric layer of the second information storage layer 163 may be a material in which at least one of HfO₂, ZrO2, and HZO is doped with at least one of impurities, Zr, C, Si, Mg, Al, Y, N, Ge, Sn, Gd, La, Sc, and Sr. For example, the ferroelectric layer of the second information storage layer 163 may include Hf₁₋ₓZrₓO₂ (0≤x≤1), (Al, C, N, Gd, Y, Ta, La, Si)-doped HfO₂, or Al₁₋ₓScₓN (0≤x≤1).

The ferroelectric layer of the second information storage layer 163 is not limited to the above-described material types, and may include a material having ferroelectric properties capable of storing information. For example, the ferroelectric layer of the second information storage layer 163 may include at least one of BaTiO₃, PbTiO₃, BiFeO₃, SrTiO₃, PbMgNdO₃, PbMgNbTiO₃, PbZrNbTiO₃, PbZrTiO₃, KNbO₃, LiNbO₃, GeTe, LiTaO₃, KNaNbO₃, BaSrTiO₃, HF_{0.5}Zr_{0.5}O₂, PbZrₓTi₁₋ₓO3(0<x<1), Ba(Sr, Ti)O₃, Bi₄₋ₓLaₓTi3O12 (0<x<1), SrBi₂Ta₂O₉, Pb₅Ge₅O₁₁, SrBi₂Nb₂O₉, and YMnO₃. The second information storage layer 163 may be a single layer or multiple layers of the above-described ferroelectric materials.

The thickness of the second information storage layer 163 may be greater than the thickness of the first information storage layer 162. The thickness of the first information storage layer 162 may be greater than or equal to about 3 Å, and may be equal to or less than about 50 Å. The thickness of the second information storage layer 163 may be equal to or greater than about 10 Å, and may be equal to or less than about 130 Å.

The second insulating layer 161 disposed between the first information storage layer 162 and the gate electrode 185 may include an insulating material such as silicon oxide.

The semiconductor device 100 may further include a first horizontal insulating layer 210 and a second horizontal insulating layer 220 on the second substrate 201.

The first horizontal insulating layer 210 is disposed on the second substrate 201 with a first thickness h1, and the back gate contact 135 in the second horizontal insulating layer 220 and the second substrate 201 may be physically spaced apart. The first horizontal insulating layer 210 may be formed of the same material as the interlayer insulating layers 120, but is not limited thereto. As an example, the first horizontal insulating layer 210 may include silicon oxide.

The second horizontal insulating layer 220 may be disposed on the first horizontal insulating layer 210. The second horizontal insulating layer 220 may be formed of a material different from the first horizontal insulating layer 210 to have etch selectivity. For example, the second horizontal insulating layer 220 may include silicon nitride or silicon oxynitride.

An upper insulating layer 230 may be disposed on the second horizontal insulating layer 220. The upper insulating layer 230 includes a multi-layer insulating layer, a plurality of vias and upper wires may be disposed therein, and the upper insulating layer 230 may include an insulating material, such as silicon oxide, silicon nitride, silicon carbide, or silicon oxynitride.

The back gate contacts 135 may be disposed on the second substrate 201. The back gate contacts 135 are electrically and physically connected to the upper surface of the back gate electrode 130 in each vertical structure CH, and may include a via structure connected to the back gate line (BGL) of the upper interconnection 240 on the upper insulating layer 230.

Each of the back gate contacts 135 may include a pad region 135H disposed in the second horizontal insulating layer 220 and a via region 135V that protrudes upward from the pad region 135H in the Z-direction and penetrates the upper insulating layer 230.

The pad region 135H of the back gate contacts 135 may penetrate the second horizontal insulating layer 220 and have a width W3 greater than the upper surface of the back gate electrode 130, and the width W3 of the pad region 135H may be equal to or smaller than the lower width W1 of the vertical structure CH. For example, the width W3 of the pad region 135H may be greater than the upper width W2 and smaller than the lower width W1 of the vertical structure CH. For example, the pad region 135H has an area that enlarged horizontally to be larger than the width W2 of the upper surface of the back gate electrode 130 of the vertical structure CH. Therefore, even if mis-alignment occurs when forming a hole for the via region 135V of the upper back gate contact 135, short circuits and the like may be limited and/or prevented. By forming the width W3 of the pad region 135H to be equal to or smaller than the lower width W1 of the vertical structure CH, the separation distance from the adjacent vertical structure CH may be maintained.

A via region 135V is formed that protrudes upward from the pad region 135H in the Z-direction and penetrates the upper insulating layer 230, and the via region 135V may have an inclined side surface such that the width W4 of the upper surface is larger than the width of the lower surface.

For example, the via region 135V may penetrate the upper insulating layer 230 and have an upper surface that is coplanar with the upper surface of the upper insulating layer 230. The width W4 of the upper surface of the via region 135V may be smaller than the width W3 of the pad region 135H and larger than the width of the upper surface of the back gate electrode 130.

The back gate contact 135 may further include a protrusion 135P that protrudes downward from the pad region 135H toward the upper surface of the back gate electrode 130. The protrusion 135P may extend between the first insulating layers 131 to the upper surface of the back gate electrode 130 and contact the upper surface of the back gate electrode 130.

As illustrated in FIGS. 3 to 4B, the vertical structure CH may have an annular pillar shape symmetrical about the center line lc of the width of the lower or upper surface, and in a vertical cross-section, the back gate electrode 130 has a pillar shape with respect to the center line lc. Respective layers surrounding the back gate electrode 130, in detail, the first insulating layer 131, the channel layer 150 and the gate dielectric structure 160, may be formed symmetrically about the center line lc as an axis, and may be formed to have a U-shaped or cylindrical shape.

The back gate contact 135 may also be formed symmetrically about the center line lp of the width of the pad region 135H and the via region 135V. The center line lp of the back gate contact 135 may be generally defined as the center line lp of the width of the upper or lower surface of the via region 135V, and may also be defined as the center line lp of the width W3 of the pad region 135H. The center line lc of the vertical structure CH and the center line lp of the back gate contact 135 may be coaxial with each other. When the center line lc of the vertical structure CH and the center line lp of the back gate contact 135 are coaxial with each other, by forming a hole for the via region 135V of the back gate contact 135, and by filling the hole with the conductive material 135a, electrical connection from the back gate electrode 130 to the upper back gate line 240 may be implemented.

Like the back gate electrode 130, the back gate contact 135 may further include a barrier layer 135b on the side and lower surfaces, and the barrier layer 135b may function as a diffusion barrier. As the conductive material layer 135a therein, tungsten (W), copper (Cu), aluminum (Al), or the like may be included, and the barrier layer 135b may include at least one of titanium (Ti), titanium nitride (TiN), tantalum (Ta), tantalum nitride (TaN), and tungsten nitride (WN).

Between the back gate contact 135 and the back gate electrode 130, in detail, at the interface between the protrusion 135P of the back gate contact 135 and the upper surface of the back gate electrode 130, the barrier layer 135bb may be further included. Accordingly, the barrier layer 135bb may be disposed on the lower surface of the protrusion 135P, and the level of the barrier layer 135bb may be the same as the level of the upper surface of the second substrate 201, but is not limited thereto.

In this manner, each back gate contact 135 is aligned with the vertical structure CH in the Z-direction and is connected to the upper surface of the back gate electrode 130, allowing current to flow from the upper interconnection 240, which is the upper back gate line.

In this manner, the first insulating layer 131 protrudes from the upper surface of the second substrate 201 and extends to contact the lower surface of the pad region 135H of the back gate contact 135, and the upper surface of the channel layer 150 and the back gate electrode 130 may be coplanar with the upper surface of the second substrate 201.

The channel layer 150 is physically spaced laterally from the pad region 135H and the protrusion 135P of the back gate contact 135 by the first insulating layer 131, and the channel layer 150 and the second substrate 201 are physically spaced vertically from the pad region 135H of the back gate contact 135 by the first horizontal insulating layer 210 to maintain an insulating structure.

The upper interconnection 240 including the back gate line may be implemented as a plate layer commonly connected to a plurality of vertical structures CH on the second substrate 201, and current may flow by simultaneously applying the same back gate voltage to one block or multiple blocks of vertical structures CH.

The upper interconnection 240 including the back gate line may be disposed at a higher level than the upper surface of the second substrate 201, based on the upper surface of the first substrate 3, and the upper interconnection 240 including the back gate line may contact the upper surface of the via regions 135V of the back gate contacts 135.

The upper interconnection 240 including the back gate line may include a conductive material, and for example, may include a metal material such as tungsten (W), copper (Cu), aluminum (Al), gold (Au), or silver (Ag).

The upper interconnection structure 140 may electrically connect the vertical structures CH to the circuit elements 12. The upper interconnection structure 140 may include a channel contact plug 147 and an upper interconnection line. The channel contact plug 147 may be connected to the pad region 157 of the vertical structure CH. The channel contact plug 147 may be electrically connected to the channel layer 150 through the pad region 157 of the vertical structures CH in the memory cell array area. The upper interconnection line of the upper interconnection structure 140 may be connected to the channel contact plug 147. The upper interconnection structure 140 may include a conductive material, for example, tungsten (W), copper (Cu), aluminum (Al), etc., and each component may further include a diffusion barrier comprising at least one of titanium (Ti), titanium nitride (TiN), tantalum (Ta), tantalum nitride (TaN), and tungsten nitride (WN). According to some example embodiments, the number and arrangement of layers constituting the upper interconnection structure may be changed in various manners.

The upper bonding structure 180 may be connected to the upper interconnection structure 140. For example, the channel contact plug 147 may be electrically connected to the upper bonding structure 180. The upper bonding structure 180 may include an upper bonding via, an upper bonding pad 184, and an upper bonding insulating layer 186. The upper bonding via may be connected to the upper interconnection structure 140. The upper bonding pad 184 may be connected to the upper bonding via. The upper bonding via and the upper bonding pad 184 may include a conductive material, for example, tungsten (W), copper (Cu), aluminum (Al), etc., and each component may further include a diffusion barrier. The upper bonding insulating layer 186 may also function as a diffusion barrier layer for the upper bonding pad 184 and may include at least one of SiCN, SiO, SiN, SiOC, SiON, and SiOCN. The upper bonding insulating layer 186 may have a thickness thinner than the thickness of the upper bonding pad 284, but is not limited thereto.

The upper capping layer 190 may be disposed below the second substrate 201 and cover the second substrate 201, the upper insulating layer 230, and the gate electrodes 185. The upper capping layer 190 may include a plurality of insulating layers. The upper capping layer 190 may include an insulating material, for example, silicon oxide, silicon nitride, silicon oxynitride, or silicon oxycarbide.

In some example embodiments, the vertical structure CH may include the first information storage layer 162 and the second information storage layer 163 between the gate electrode 185 and the back gate electrode 130.

The semiconductor device 100 according to some example embodiments may include the first information storage layer 162 capable of storing information using a charge trap, and the second information storage layer 163 capable of storing information using a polarization state. In this manner, in the memory cell transistor including the first information storage layer 162 and the second information storage layer 163 that may store information in different ways, the difference between the threshold voltage of the memory cell transistor in a programmed state and the threshold voltage of the memory cell transistor in an erased state may be large. As the threshold voltage difference between the programmed state and the erased state is large, the memory window may be increased.

In a program operation, a back gate voltage may be applied to each memory cell to maintain the polarization state of the second information storage layer 163 of an unselected cell among the second information storage layers 163.

Therefore, when a selected cell of the second information storage layer 163 performs a program operation, a back gate voltage may be applied to limit and/or prevent the polarization charges of the second information storage layer 163 of the unselected cells, which are neighboring cells, from being affected and depolarized by the program voltage.

Therefore, the memory window may be limited and/or prevented from decreasing due to depolarization of the second information storage layer 163.

Hereinafter, the operation of the semiconductor device 100 including the memory cell transistor MCT will be described with reference to FIGS. 5A and 5B.

Program operation may include applying a program voltage (Vpro) greater than 0V to the word line WL, for example, the gate electrode 185, of the selected cell transistor, grounding (0V) the bit line BL and the channel layer 150, and lowering the threshold voltage of selected cell transistors, as illustrated in FIG. 5A.

In the above program operation, by applying a program voltage (Vpro) of about 20V or more to the word line and gate electrode 185, and grounding (0V) the bit line BL and the channel layer 150, a first polarization state may be formed in which positive charges are aligned on the first side 163S1 adjacent to the channel layer 150 and negative charges are aligned on the second side 163S2 adjacent to the gate electrode 185, within the second information storage layer 163, which may be formed of a ferroelectric layer. By this program operation, the selected cell transistor including the second information storage layer 163 may be in a programmed state.

By the program operation, as the first polarization state is obtained in which positive charges are aligned adjacent to the channel layer 150 and negative charges are aligned adjacent to the gate electrode 185 within the second information storage layer 163, which may be a ferroelectric layer, the threshold voltage of the selected cell transistor may be lowered. A pass voltage (Vpass) is applied to the gate electrode 185 of the neighboring cell that is not programmed to maintain the previous second polarization state. The second polarization state may be defined as a state in which positive charges are aligned on the second side 163S2 adjacent to the gate electrode 185, and negative charges are aligned on the first side 163S1 adjacent to the channel layer 150. The pass voltage (Vpass) may be at a lower level than the program voltage (Vpro) and may be about 5V. When the pass voltage (Vpass) is applied to the gate electrode 185 of the unselected cell transistor and the program voltage (Vpro) is applied to the selected gate electrode 185, the second polarization state of the cell transistor of the unselected gate electrode 185 may be shaken by the high program voltage (Vpro) of the neighboring cell transistor. To maintain the second polarization state, the back gate voltage (Vpass) may be set to the same level as the pass voltage (Vpass) on the back gate electrode 130. Therefore, the same level of voltage (Vpass) is applied to the gate electrode 185 and the back gate electrode 130 of the unselected cell transistor. No electric field is set in the second charge storage layer 163 of the unselected cell transistor.

Therefore, the second polarization state of the unselected cell transistor is not affected and the second polarization state may be maintained even by the high program voltage (Vpro) of the neighboring gate electrode 185.

On the other hand, as illustrated in FIG. 5B, in the memory cell transistor, the erase operation may include grounding (0V) the gate electrodes 185, which are the word lines, and applying an erase voltage (Vera) to the channel layer 150 through the bit line BL and the source structure, for example, the second substrate 201 to increase the threshold voltage of the memory cell transistor. For example, the gate electrode 185, which is the word line, is grounded, and by applying a voltage of 0V to the back gate electrode 130 to be grounded, and applying an erase voltage (Vera) of about 15V or more to the channel layer 150, at the same time as electrons are injected from the gate electrode 185, which is the word line, into the gate dielectric structure 160, a second polarization state in which positive charges are aligned adjacent to the gate electrode 185 and negative charges are aligned adjacent to the channel layer 150 may be formed within the second information storage layer 163, which may be formed of a ferroelectric layer. In the programmed state, the second information storage layer 163 may be in the first polarization state, and due to the erase operation, the polarization direction of the second information storage layer 163 switches from the first polarization state to the second polarization state. For example, the direction of polarization of the second information storage layer 163 may be switched by the program operation or the erase operation.

By the erase operation, the second information storage layer 163, which may be a ferroelectric layer, simultaneously enters the second polarization state, and the threshold voltage of the memory cell transistor MCT may increase.

As described above, in the memory cell transistor MCT including the second information storage layer 163, a memory window may be set based on the difference between the threshold voltage of the memory cell transistor MCT in a programmed state and the threshold voltage of the memory cell transistor MCT in an erased state. Additionally, to significantly reduce the influence of the polarization state of unselected neighboring cells by the high program voltage of the selected cell, by setting the voltage of the back gate electrode 130 to be the same as the voltage of the gate electrode 185, the memory value may be maintained without error.

As described above, since a second information storage layer 163 that may store information using the polarization state, may be included, the memory window of the semiconductor device 100 may be increased, the endurance and retention characteristics of the semiconductor device 100 may be improved, and the operating voltage of the semiconductor device 100 may be lowered.

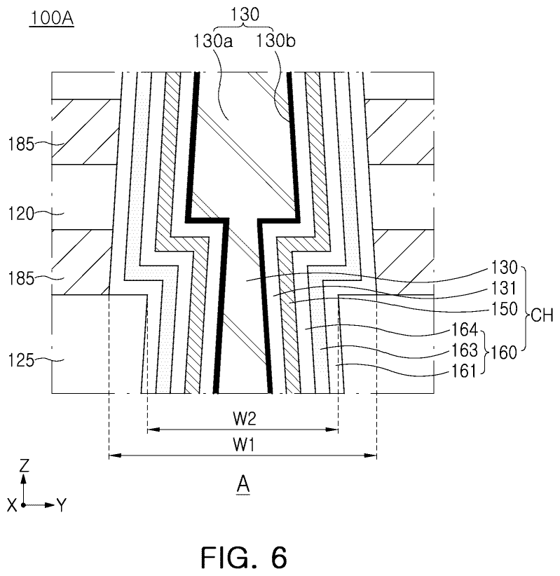

Hereinafter, various modifications of the components of the above-described embodiment will be described with reference to FIGS. 6 to 10, respectively. Various modifications to the components of the above-described embodiments described below will be explained with a focus on modified or replaced components. For example, the components described above may be quoted directly without detailed explanation, or the explanation may be omitted.

, the components that may be modified or replaced described below may improve at least one of the adhesion, reliability, performance, and productivity of the semiconductor device.

The components that may be modified or replaced below are described with reference to the drawings below, but the components that may be modified or replaced are combined with each other, or may be combined with the components described above to form a semiconductor device according to an some example embodiments.

FIGS. 6 to 8 are partial enlarged views of FIG. 4A in FIGS. 2 to 3, and FIGS. 9 and 10 are partial enlarged views of FIG. 4B in FIGS. 2 and 3.

Referring to FIG. 6, a semiconductor device 100A according to some example embodiments of the inventive concepts may be modified so that the second insulating layer 161 and the second information storage layer 163 are in direct contact without the first information storage layer 162 in the gate dielectric structure 160 described above.

The second insulating layer 161 may be disposed between the gate electrode 185 and the second information storage layer 163, and the second information storage layer 163 may contact the interface insulating layer 164. Therefore, since there is no first information storage layer 162, memory may be stored through the polarization phenomenon of the second information storage layer 163 without adjusting the threshold voltage by charge trap.

The first insulating layer 131, the interface insulating layer 164, and the second insulating layer 161 may be formed of the same material and may include silicon oxide, silicon oxynitride, or silicon oxycarbide.

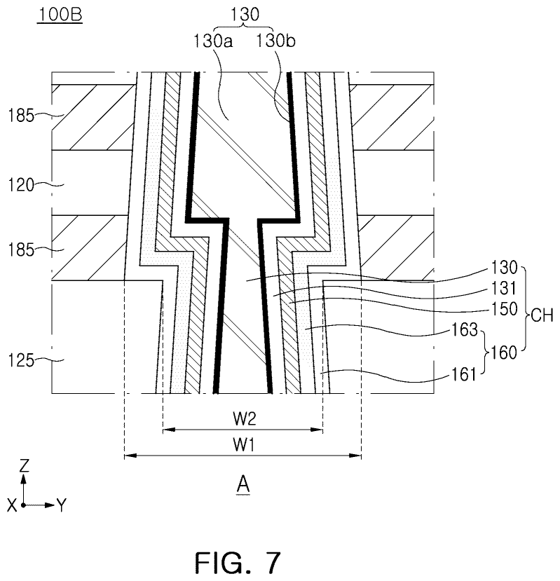

Referring to FIG. 7, a semiconductor device 100B according to some example embodiments of the inventive concepts may be modified so that the second insulating layer 161, the second information storage layer 163, and the channel layer 150 are in direct contact without the first information storage layer 162 and the interface insulating layer 164 in the gate dielectric structure 160 described above.

The second insulating layer 161 may be disposed between the gate electrode 185 and the second information storage layer 163, and the second information storage layer 163 may directly contact the channel layer 150. Therefore, since there is no first information storage layer 162, the memory may be stored through the polarization phenomenon of the second information storage layer 163 without adjusting the threshold voltage by charge trap and may directly contact the channel layer 150 without the interface insulating layer 164.

The first insulating layer 131 and the second insulating layer 161 may be formed of the same material and may include silicon oxide, silicon oxynitride, or silicon oxycarbide.

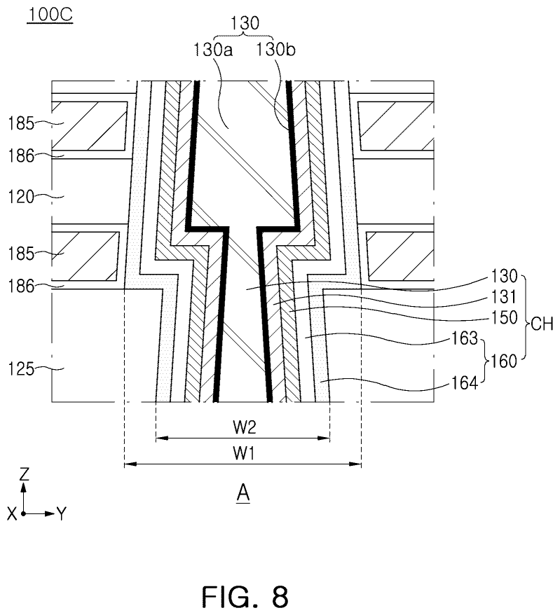

Referring to FIG. 8, in a semiconductor device 100C according to some example embodiments of the inventive concepts, the second information storage layer 163 and the channel layer 150 may be in direct contact without the first information storage layer 162 and the interface insulating layer 164 in the gate dielectric structure 160 described above, and a gate insulating layer 186 may be disposed surrounding the gate electrode 185. For example, the gate insulating layer 186 may be disposed on each gate electrode 185 to surround the upper, side, and lower surfaces, and accordingly, an insulating layer may be disposed between the gate electrode 185 and the second information storage layer 163, but the insulating layer may not be formed surrounding the channel hole.

The first insulating layer 131 may be formed of SiO₂, SiN, SiON, (Hf, Zr, Al, C, N, Gd, Y, Ti, La, Ta)-doped Si(O)N, or combinations thereof, but is not limited thereto, and the gate insulating layer 186 may include silicon oxide, silicon oxynitride, or silicon oxycarbide. Additionally, through various modifications, the arrangement of the channel layer 150 and the second information storage layer 163 may be switched.

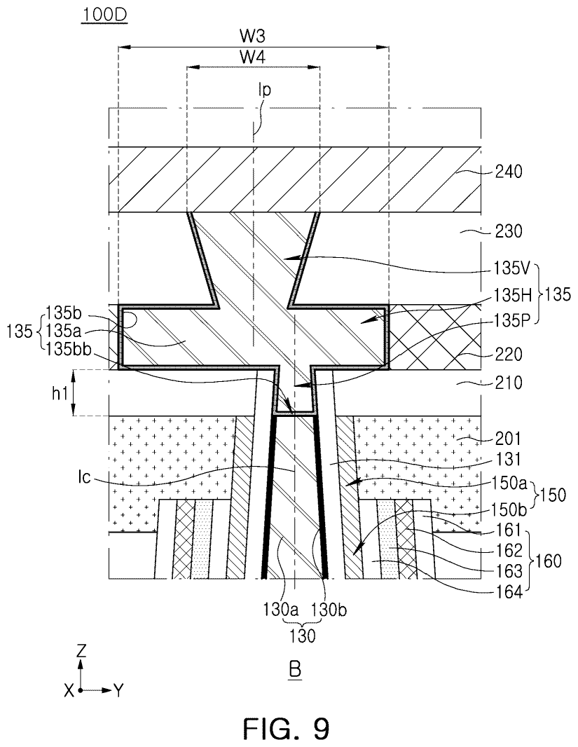

On the other hand, referring to FIG. 9, in a semiconductor device 100D according to some example embodiments of the inventive concepts, the vertical structure CH may have an annular pillar shape with respect to the center line (lc), and in a vertical cross-section, the back gate electrode 130 has a pillar shape with respect to the center line (lc), and respective layers surrounding the back gate electrode 130, in detail, the first insulating layer 131, the channel layer 150, and the gate dielectric structure 160, may be formed in a U shape symmetrical with respect to the center line lc.

The pad region 135H and the via region 135V of the back gate contact 135 may be formed symmetrically with respect to the center line lp. In the semiconductor device 100D according to some example embodimentsof the inventive concepts, the center line lc of the vertical structure CH and the center line lp of the back gate contact 135 may not be coaxial with each other. For example, the center line lp of the back gate contact 135 may be offset within the pad region 135H with respect to the center line lc of the vertical structure CH. If the center line lc of the vertical structure CH and the center line lp of the back gate contact 135 are not coaxial with each other, after the channel layer 150 is formed, when forming a hole for the back gate contact 135 thereon, the hole may be formed offset by a desired (and/or alternatively predetermined) distance to limit and/or prevent damage to the vertical structure CH. In this manner, within the pad region 135H of the back gate contact 135, the upper via region 135V and the lower back gate electrode 130 are electrically connected to each other in the offset state, thereby forming the channel layer 150 during the process. Damage of the channel layer 150 may be significantly reduced.

In this manner, even when the center line lc of the vertical structure CH and the center line lp of the back gate contact 135 are offset, a hole is formed for the via region 135V of the back gate contact 135, and by filling the hole with the conductive material, an electrical connection may be implemented from the back gate electrode 130 to the upper interconnection 240 including the upper back gate line.

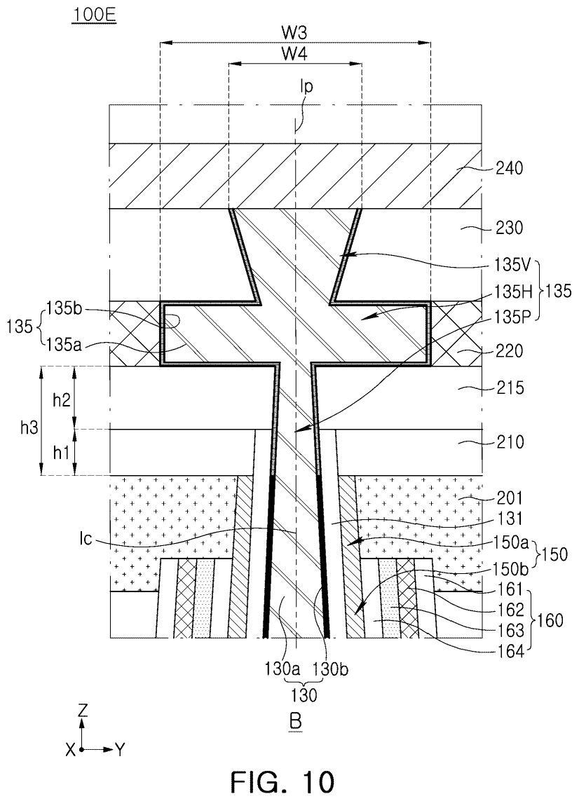

On the other hand, referring to FIG. 10, a semiconductor device 100E according to some example embodiments of the inventive concepts may further include a third horizontal insulating layer 215 between the first horizontal insulating layer 210 and the second horizontal insulating layer 220.

The third horizontal insulating layer 215 has a second thickness h2, and is formed on the upper surfaces of the first horizontal insulating layer 210 and the first insulating layer 131, and the back gate contact 135 may penetrate the third horizontal insulating layer 215 and directly contact the side surface.

The third horizontal insulating layer 215 may be formed of the same material as the first horizontal insulating layer 210, and may be silicon oxide or silicon carbonate, but is not limited thereto. The third horizontal insulating layer 215 may include a material having etch selectivity with respect to a second horizontal insulating layer 220.

In this manner, by further including the third horizontal insulating layer 215, the separation distance h3 between the pad region 135H of the back gate contact 135, the second substrate 201, and the channel layer 150 may be increased. By forming a bent portion extending from the pad region 135H to the protrusion 135P using the third horizontal insulating layer 215, a short circuit between the channel layer 150 and the pad region 135H may be limited and/or prevented.

The back gate electrode 130 and the back gate contact 135 may further include barrier layers 130b and 135b on side and lower surfaces. The barrier layers 130b and 135b are diffusion barriers, and may include tungsten (W), copper (Cu), aluminum (Al), or the like, as conductive material layers 130a and 135a therein. The barrier layers 130b and 135b may include at least one of titanium (Ti), titanium nitride (TiN), tantalum (Ta), tantalum nitride (TaN), and tungsten nitride (WN).

Between the back gate contact 135 and the back gate electrode 130, in detail, on the protrusion 135P of the back gate contact 135 and the upper surface of the back gate electrode 130, conductive materials may be filled in succession without boundaries, unlike FIG. 4B. For example, the barrier layer 135bb at the boundary as illustrated in FIG. 4B does not exist and may be formed integrally.

In this manner, each back gate contact 135 is aligned with the vertical structure CH in the Z-direction and extends while contacting the upper surface of the back gate electrode 130, thereby allowing current to flow from the upper back gate line 240.

The first insulating layer 131 protrudes from the upper surface of the second substrate 201 and may be formed to contact the lower surface of the third horizontal insulating layer 215.

The channel layer 150 and the second substrate 201 are physically spaced laterally from the pad region 135H of the back gate contact 135 by the first insulating layer 131, and the first horizontal insulating layer 210 and the third horizontal insulating layer 215 may be physically further spaced h3 from the pad region 135H of the back gate contact 135 on the upper surface to maintain an insulating structure.

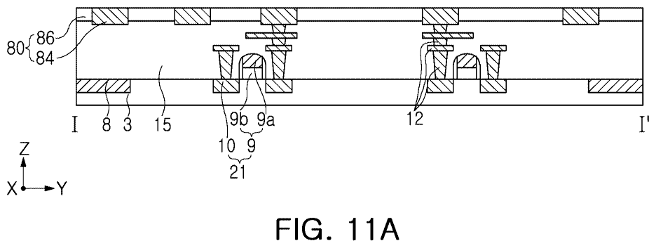

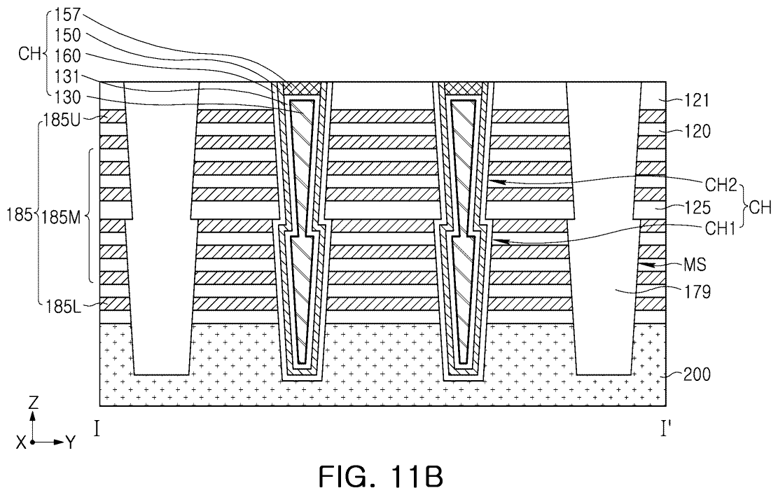

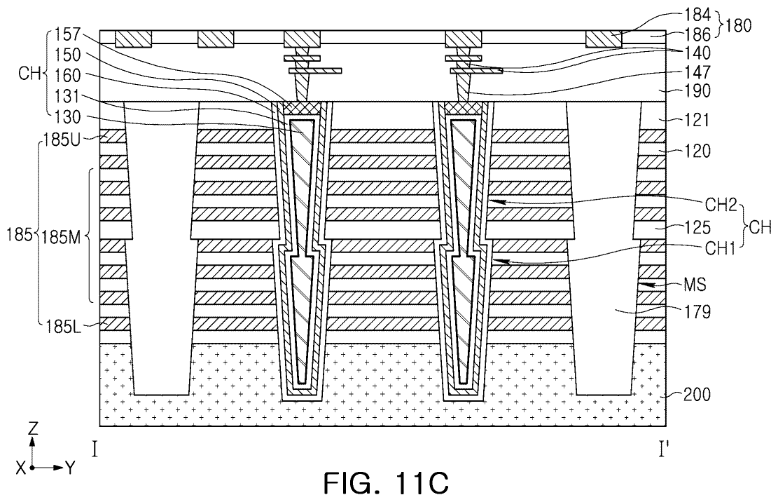

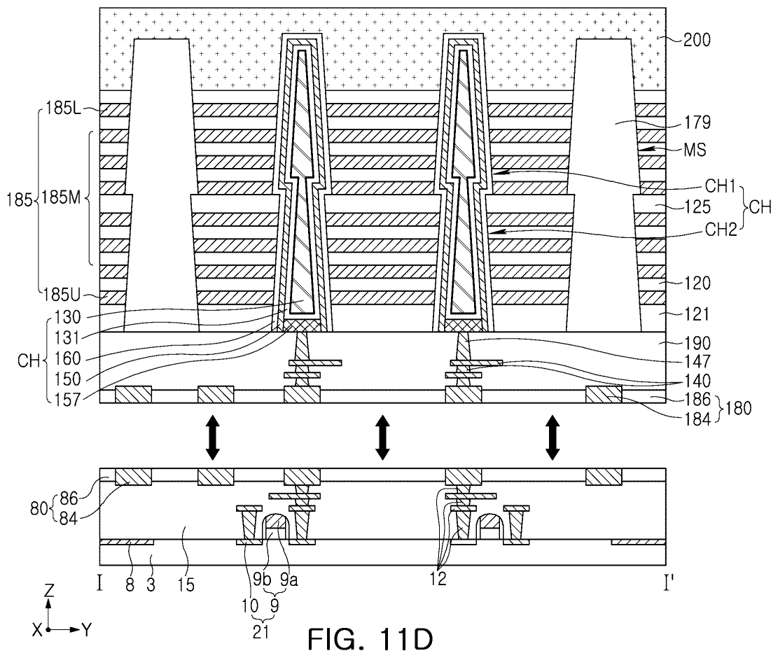

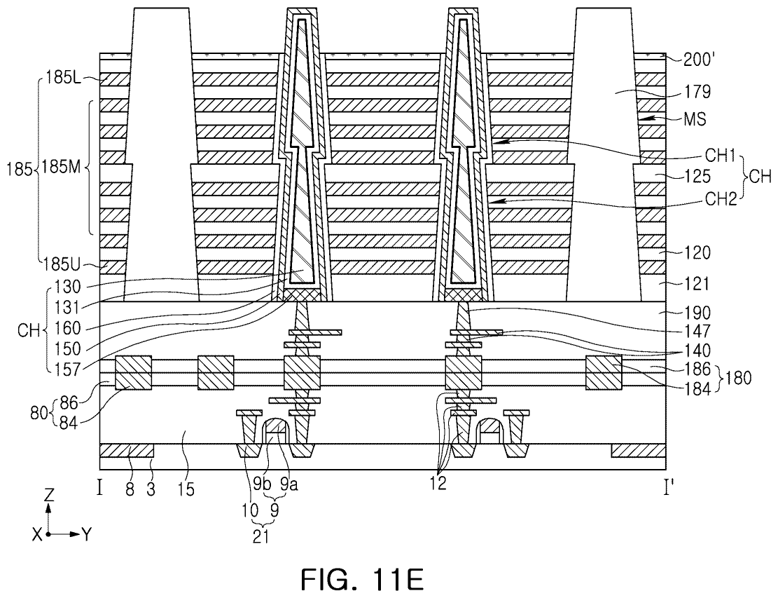

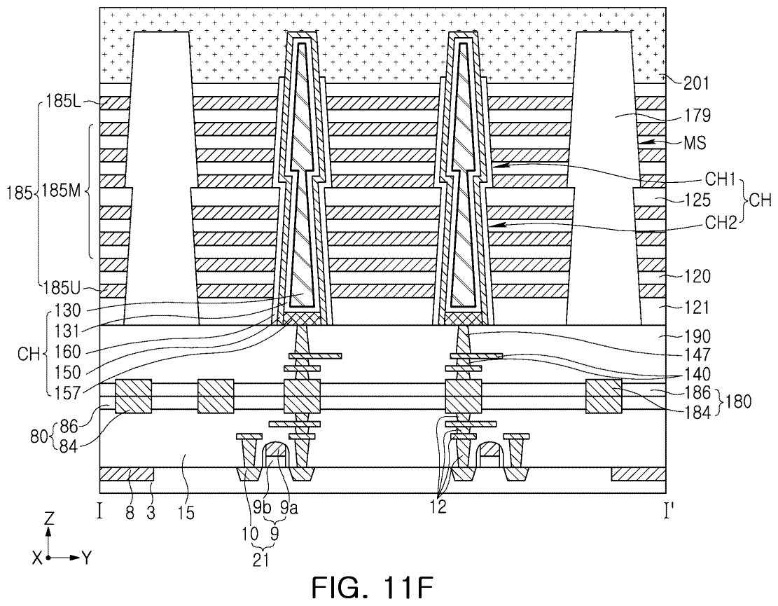

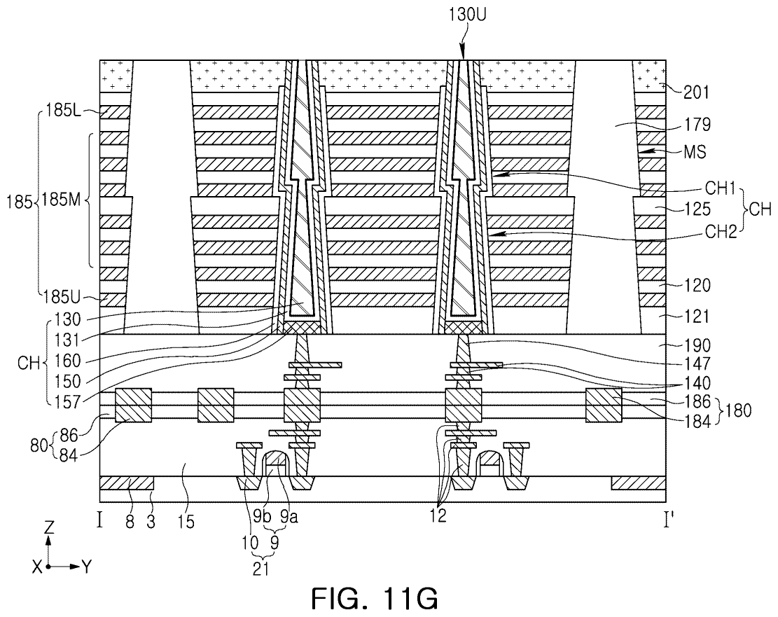

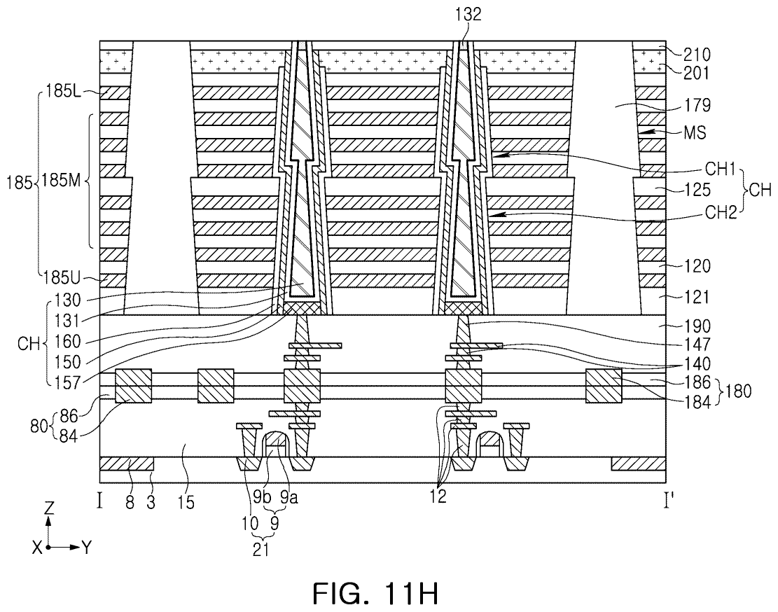

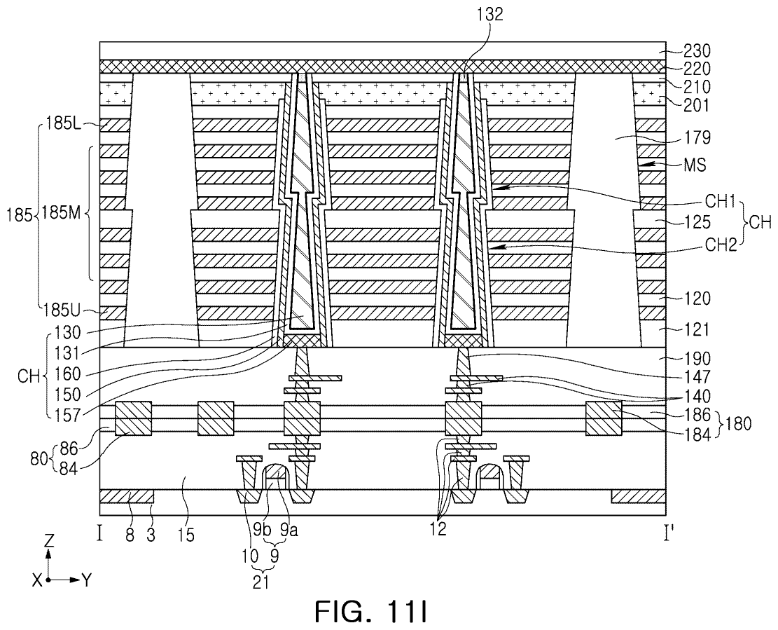

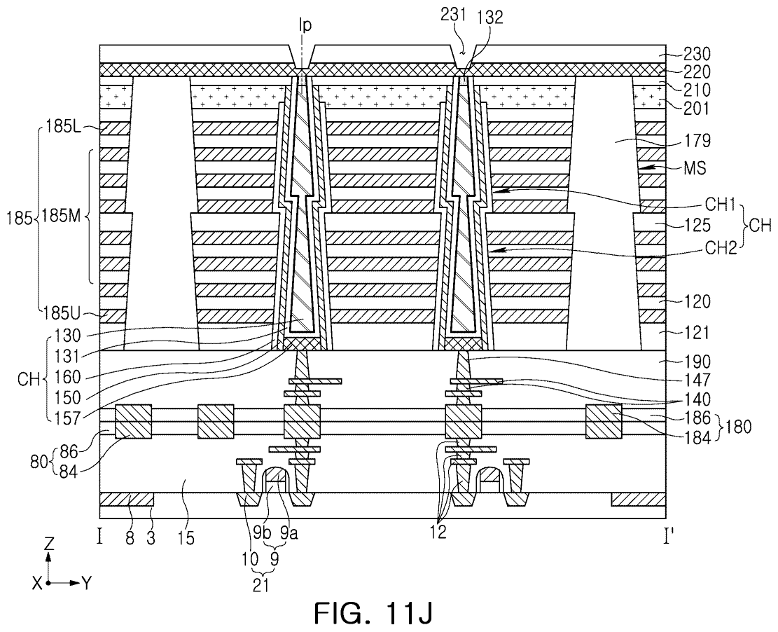

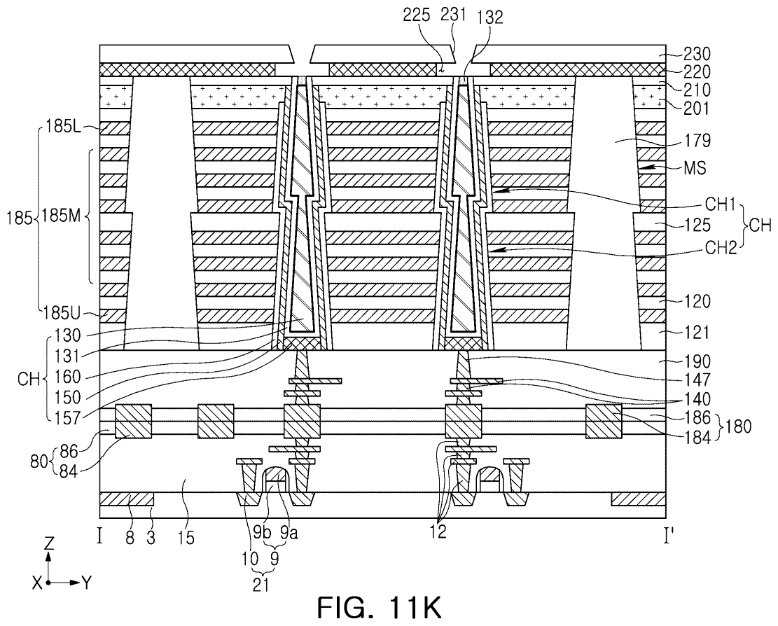

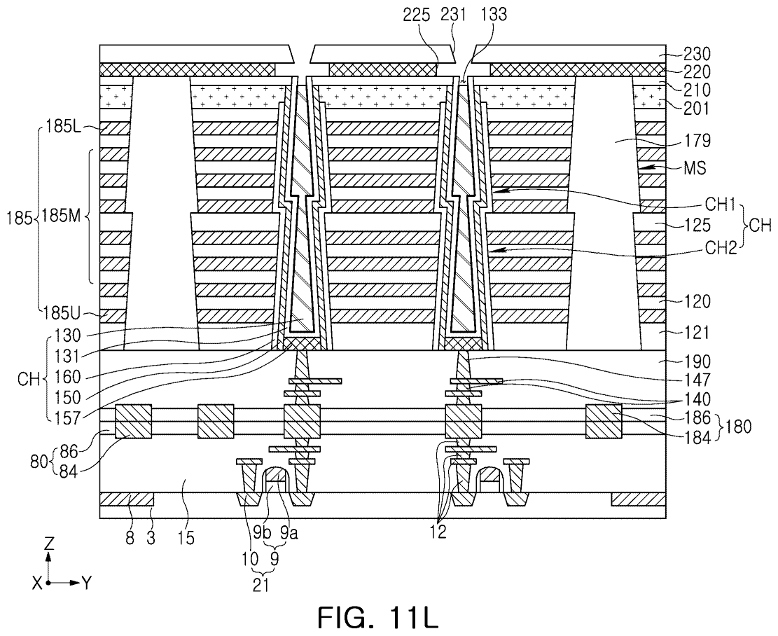

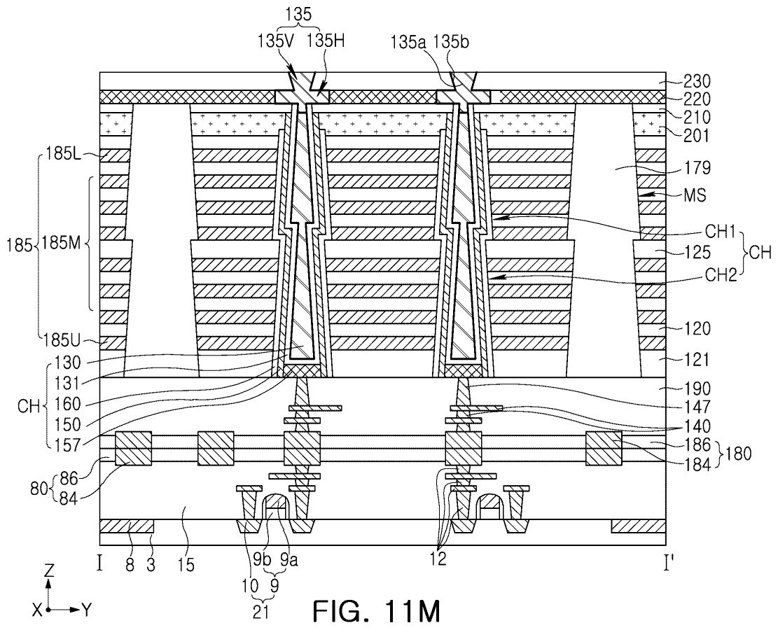

Next, with reference to FIGS. 11A to 11M, an example of a method of forming a semiconductor device according to some example embodiments will be described. FIGS. 11A to 11D are cross-sectional views illustrating a region cut along line II′ of FIG. 2 to illustrate an example of a method of forming a semiconductor device according to some example embodiments.

Referring to FIG. 11A, circuit elements 21, a lower interconnection structure 12, a lower bonding structure 80, and a lower capping layer 15 forming the second region PERI on the first substrate 3 may be formed.

First, device isolation layers 8 may be formed in the first substrate 3, and the circuit gate dielectric layer 9b and the circuit gate electrode 9a may be sequentially formed on the first substrate 3. The device isolation layers 8 may be formed by, for example, a shallow trench isolation (STI) process. A circuit gate dielectric layer 9b may be formed on the first substrate 3, and a circuit gate electrode 9a may be formed on the circuit gate dielectric layer 9b. The circuit gate dielectric layer 9b and the circuit gate electrode 9a may be formed using atomic layer deposition (ALD) or chemical vapor deposition (CVD). The circuit gate dielectric layer 9b is formed of silicon oxide, and the circuit gate electrode 9a may be formed of at least one of polycrystalline silicon or a metal silicide layer, but is not limited thereto. Next, spacer layers are formed on both side walls of the circuit gate dielectric layer 9b and the circuit gate electrode 9a, and source/drain regions 10 may be formed by injecting impurities into the active region of the first substrate 3 from both sides of the circuit gate electrode 9a.

Among the lower interconnection structures 12, the lower contact plugs may be formed by forming a portion of the lower capping layer 15, then removing the portion by etching, and then filling the portion with a conductive material. Lower interconnection lines may be formed, for example, by depositing a conductive material and then patterning the same.

The lower bonding via of the lower bonding structure 80 may be formed by forming a portion of the lower capping layer 15, then removing the portion by etching and filling the portion with a conductive material. The lower bonding pad 84 may be formed, for example, by depositing a conductive material and then patterning the same. The lower bonding structure 80 may be formed by, for example, a deposition process or a plating process. The lower bonding insulating layer 86 may be formed by covering a portion of the top and side surfaces of the lower bonding pad 84 and then performing a planarization process until the upper surface of the lower bonding pad 84 is exposed.

The lower capping layer 15 may be composed of a plurality of insulating layers. The lower capping layer 15 may be part of each operation of forming the lower interconnection structure 12 and the lower bonding structure 80. As a result, a second region PERI may be formed.

Referring to FIG. 11B, a stack structure ST and vertical structures CH may be formed on the base substrate 200. The base substrate 200 may include a semiconductor material, such as a group IV semiconductor, a group III-V compound semiconductor, or a group II-VI compound semiconductor. The base substrate 200 may be provided to control the thickness of the second substrate 201 in the process operation of removing the base substrate 200 below.

Sacrificial insulating layers and interlayer insulating layers 120 are alternately stacked to form a lower stack structure, and the sacrificial insulating layers and the interlayer insulating layers 120 may be alternately stacked to form an upper stack structure. Next, vertical structures CH that penetrate the stack structure of the sacrificial insulating layers and the interlayer insulating layers 220 may be formed. A separation opening penetrating through the stack structure of the sacrificial insulating layers and the interlayer insulating layers 120 may be formed in an area corresponding to the separation area MS (see FIG. 2B). The sacrificial insulating layers may be layers that are partially replaced with the gate electrodes 185 through a subsequent process.

Vertical sacrificial structures may be formed to penetrate the lower stack structure. The vertical sacrificial structures may be formed by anisotropically etching the lower stack structure of the sacrificial insulating layers and interlayer insulating layers 120 using a mask layer, and may be formed by forming hole-shaped lower channel holes and then filling the same. The vertical sacrificial structure may include a semiconductor material such as polycrystalline silicon. According to some example embodiments, the vertical sacrificial structure may include at least one of silicon oxide, silicon nitride, and silicon oxynitride. After forming the vertical sacrificial structure, an upper stack structure of sacrificial insulating layers and interlayer insulating layers 120 may be formed on the lower stack structure and the vertical sacrificial structure.

Next, an upper interlayer insulating layer 121 may be formed that covers the stack structure of the sacrificial insulating layers and the interlayer insulating layers 120.

The vertical structures CH may be formed by forming upper holes on the vertical sacrificial structure, removing the vertical sacrificial structure to form hole-shaped channel holes, and filling the channel holes with a plurality of layers. As described above, the plurality of layers may include a gate dielectric structure 160, a channel layer 150, a first insulating layer 131, a back gate electrode 130, and a pad pattern 157. The upper channel holes of the channel holes may be formed by anisotropically etching the upper stack structure ST of the sacrificial insulating layers and the interlayer insulating layers 120 using a separate mask layer. The lower channel holes of the channel holes may be formed by removing the vertical sacrificial structure exposed through the upper channel holes.

Due to the height of the stack structure ST, the sidewalls of the vertical structures CH may not be perpendicular to the upper surface of the base substrate 200. The vertical structures CH may be formed to recess a portion of the base substrate 200.

The gate dielectric structure 160 may be formed as a multilayer structure, as illustrated in FIGS. 4A and 4B. As an example, the second insulating layer 161, the first information storage layer 162, the second information storage layer 163, and the interface insulating layer 164 may be sequentially stacked in the channel hole.

The channel layer 150 may be formed on gate dielectric structure 160 within vertical structures CH. The first insulating layer 131 may be formed on the channel layer 150, and the back gate electrode 130 may be formed to fill the vertical structure CH and may be formed of a conductive material. The back gate electrode 130 may be formed by first forming a barrier layer 130b on the side, top, and lower surfaces and then filling the inside with a conductive material layer 130a, but is not limited thereto.

For example, the barrier layer 130b may not be formed on the lower surface. Next, the first insulating layer 131 may be formed on the upper surface of the back gate electrode 130, and a pad pattern 157 may be formed on the first insulating layer 131. The pad pattern 157 may be formed of a conductive material, for example, polycrystalline silicon.

The sacrificial insulating layers may be removed through the separation opening and filled with a conductive material to form gate electrodes 185. The separation region MS may be formed by filling the separation opening with the separation insulating layer 179.

The conductive material may include metal, polycrystalline silicon, or metal silicide material. After forming the gate electrodes 185, the conductive material deposited in the separation opening may be removed through an additional process and then filled with an insulating material and a conductive material to form a separation region MS.

Referring to FIG. 11C, an upper interconnection structure including channel contact plugs 147 may be formed, and an upper bonding structure 180 may be formed. In the first region CELL, channel contact plugs 147 may be formed to be connected to the vertical structures CH.

The contact studs may be connected to each other to connect the upper interconnection lines 140 vertically.

The upper bonding structure 180 may be formed in a similar manner to forming the lower bonding structure 80. As a result, the first region CELL may be formed. However, during the manufacturing process of the semiconductor device, the first region CELL may further include the base substrate 200.

Referring to FIG. 11D, the first semiconductor structure in the second region PERI and the second semiconductor structure in the first region CELL may be bonded.

The second region PERI and the first region CELL may be connected by bonding the lower bonding pad 84 and the upper bonding pad 184 by applying pressure. The lower bonding insulating layer 86 and the upper bonding insulating layer 186 may be connected by bonding the same using pressure. The first region CELL is turned over on the second region PERI, and the upper bonding pad 184 may be bonded to face downward. The second region PERI and the first region CELL may be directly bonded without the intervention of an adhesive such as a separate adhesive layer.

Referring to FIG. 11E, the base substrate 200 and the gate dielectric structure 160 on the vertical structure CH may be removed. First, the base substrate 200 may be removed. A portion of the base substrate 200 is removed from the upper surface by a polishing process such as a grinding process, and the remaining part may be removed by an etching process such as wet etching and/or dry etching. In the area where the base substrate 200′ has been removed, the separation regions MS and the vertical structures CH may have a protruding shape. Alternatively, the entire base substrate 200 may be removed through an etching process.

Next, the gate dielectric structure 160 on the vertical structure CH may be removed. Gate dielectric structure 160 may be removed by a photolithography process and an etching process such as wet etching and/or dry etching. Therefore, when the subsequent process proceeds, the channel layer 150 may contact the second substrate 201.

Referring to FIG. 11F, the second substrate 201 may be formed.

The second substrate 201 may be formed by depositing N-type doped polysilicon on the remaining base substrate 200′ or the uppermost interlayer insulating layer 120. However, some example embodiments of the inventive concepts are not limited thereto and may also be formed by depositing P-type doped polysilicon. The second substrate 201 may be formed to have a desired (and/or alternatively predetermined) thickness to cover the vertical structures CH and the separation region MS. The second substrate 201 may be formed along the protruding channel layer 150, but is not limited thereto. Because of this, the second substrate 201 and the channel layer 150 may be electrically connected.

Next, referring to FIG. 11G, the second substrate 201 and a portion of the vertical structure CH may be removed so that the back gate electrode 130 is exposed on the upper surface of the vertical structure CH. A portion of the second substrate 201 may be removed from the upper surface through chemical mechanical polishing (CMP) to form a channel layer 150 and a first insulating layer 131 until the upper surface 130U of the back gate electrode 130 is exposed.

Next, referring to FIG. 11H, the exposed upper surface of the second substrate 201 and the upper surface 130U of the back gate electrode 130 may be oxidized to form the first horizontal insulating layer 210. The first horizontal insulating layer 210 may be formed of silicon oxide by oxidizing the exposed upper surfaces of the second substrate 201 and the channel layer 150, and the exposed upper surface of the back gate electrode 130 may be formed of silicon oxide and may be oxidized to form an oxide film 132.

The thickness of the formed first horizontal insulating layer 210 may meet the first thickness h1.

Next, as illustrated in FIG. 11I, the second horizontal insulating layer 220 may be formed on the first horizontal insulating layer 210, and the upper insulating layer 230 may be formed continuously.

The second horizontal insulating layer 220 and the upper insulating layer 230 may be formed by deposition, and after depositing a silicon nitride film to form the second horizontal insulating layer 220 to a desired (and/or alternatively predetermined) thickness, an oxide film may be deposited to form the upper insulating layer 230. The upper insulating layer 230 may be formed to have a greater thickness than the second horizontal insulating layer 220, and the second horizontal insulating layer 220 may be formed to have a thickness greater than the first thickness h1 of the first horizontal insulating layer 210.

Next, as illustrated in FIG. 11J, a first opening 231 may be formed along the center line lp that is coaxial with the center line lc (e.g., see FIG. 4B) of the back gate electrode 130 of the vertical structure CH in the upper insulating layer 230 and the second horizontal insulating layer 220.

The first opening 231 is an opening area for the via region 135V of the back gate contact 135, and is formed to stop within the second horizontal insulating layer 220, and may be formed by removing a portion of the second horizontal insulating layer 220, with the second horizontal insulating layer 220 serving as an etch stop layer.

As illustrated in FIG. 11K, expansion etching is performed within the first opening 231 to selectively remove the second horizontal insulating layer 220. Accordingly, the upper and lower oxide films are not etched, and a portion of the second horizontal insulating layer 220, which is a nitride film, may be etched. Accordingly, the second opening 225 may be formed in the second horizontal insulating layer 220 to have a third width W3.

As illustrated in FIG. 11L, the oxide film 132 on the top of the back gate electrode 130 exposed through the first opening 231 and the second opening 225 may be selectively removed to form the third opening 133. The oxide film 132 may be formed of a tungsten oxide film, etc., and may be selectively removed with respect to a nitride film or an adjacent silicon oxide film.

Accordingly, the upper surface of the lower back gate electrode 130 may be exposed through the first opening 231, the second opening 225, and the third opening 133.

Next, as illustrated in FIG. 11M, the barrier film 135b is formed continuously to the exposed side surfaces of the first opening 231, the second opening 225, and the third opening 133 and the upper surface of the back gate electrode 130. Then, a conductive material is filled up to the upper surface of the back gate electrode 130 through the first opening 231, the second opening 225, and the third opening 133, to form the conductive material layer 135a, thereby forming the back gate contact 135.

Accordingly, the back gate contact 135 and the back gate electrode 130 are formed to extend, with the barrier film 135b as a boundary, and to include an enlarged pad region 135H within the second horizontal insulating layer 220, and to have a structure where the upper surface is exposed through the upper via region 135V. A physical separation space is formed between the channel layer 150, the second substrate 201, and the upper back gate contact 135 by the first insulating layer 131 and the first horizontal insulating layer 210. Short circuit between the back gate contact 135, the second substrate 201, and the channel layer 150 may be limited and/or prevented.

Next, as illustrated in FIGS. 4A and 4B, the upper interconnection 240 including the back gate line is formed at the top and connected to the via region 135V of the back gate contact 135. An interconnection extending to the upper interconnection 240 including the back gate line, the back gate contact 135, and the back gate electrode 130 may be formed.

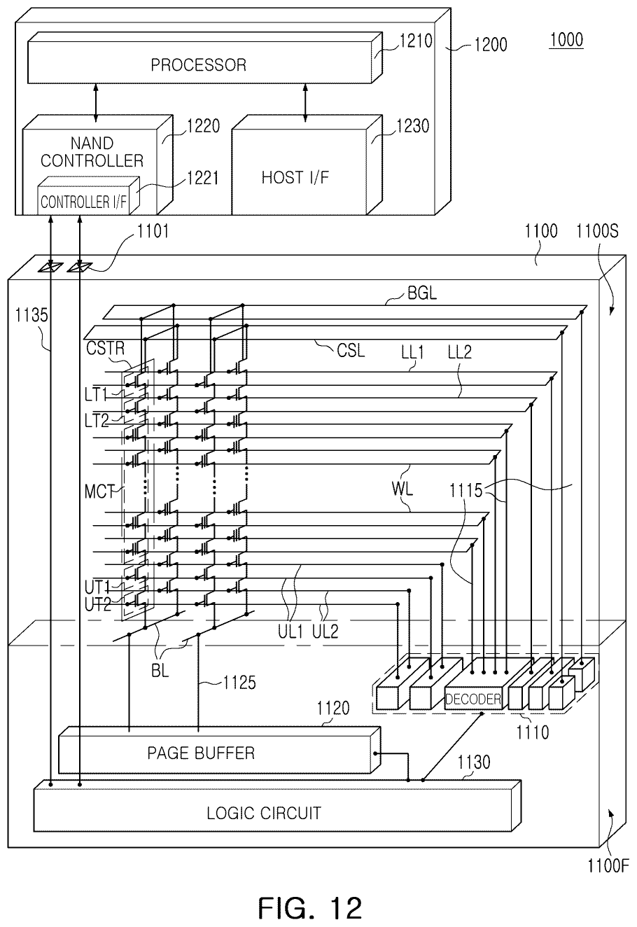

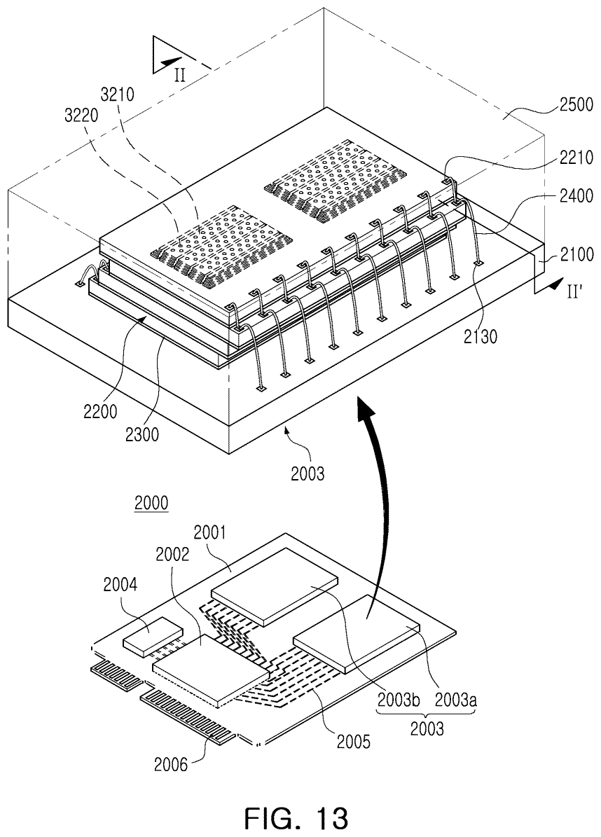

Next, a data storage system including a semiconductor device according to some example embodiments will be described with reference to FIGS. 12, 13, and 14, respectively.

FIG. 12 is a diagram schematically illustrating a data storage system including a semiconductor device according to some example embodiments.

Referring to FIG. 12, a data storage system 1000 according to some example embodiments includes a semiconductor device 1100 and may include a controller 1200 that is electrically connected to the semiconductor device 1100 and controls the semiconductor device 1100. The data storage system 1000 may be a storage device including a semiconductor device 1100 or an electronic device including a storage device. For example, the data storage system 1000 may be a solid state drive device (SSD) device, a universal serial bus (USB) device, a computing system, a medical device, or a communication device including the semiconductor device 1100.

In some example embodiments, the data storage system 1000 may be an electronic system that stores data.

The semiconductor device 1100 may be a non-volatile memory device. For example, the semiconductor device 1110 may be a semiconductor device according to any one of some example embodiments described above with reference to FIGS. 1 to 10. The semiconductor device 1100 may include a first structure 1100F and a second structure 1100S on the first structure 1100F.

The first structure 1100F may be a peripheral circuit structure including a decoder circuit 1110, a page buffer 1120, and a logic circuit 1130. For example, the first structure 1100F may include the peripheral circuit structure (PERI in FIG. 3) described above. The peripheral circuit (21 in FIG. 3) described above may include a decoder circuit 1110, a page buffer 1120, and a logic circuit 1130 that are transistors.

The second structure 1100S may be a memory structure including a bit line BL, a common source line CSL, a back gate line BGL, word lines WL, first and second gate upper lines UL1 and UL2, first and second gate lower lines LL1 and LL2, and memory cell strings CSTR between the bit line BL and the common source line CSL.

The circuit elements 21 described above may include source structures and may include a silicon layer having an N-type conductivity type, and at least portions of the source structures may constitute the common source line CSL.

In the second structure 1100S, each memory cell string CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may vary in some example embodiments.

The plurality of memory cell transistors MCTs may include the middle gate electrodes 185M, which may be word lines, the channel layer 150, the back gate electrode 130, and the second information storage layer 163 of the vertical structure CH, as described in FIG. 3.

In some example embodiments, the upper transistors UT1 and UT2 may include string selection transistors, and the lower transistors LT1 and LT2 may include ground selection transistors. The gate lower lines LL1 and LL2 may be gate electrodes of the lower transistors LT1 and LT2, respectively. The word lines WL may be gate electrodes of memory cell transistors (MCT), and the gate upper lines UL1 and UL2 may be gate electrodes of the upper transistors UT1 and UT2, respectively.

The gate electrodes (185 in FIG. 3) described above may form the gate lower lines LL1 and LL2, the word lines WL, and the gate upper lines UL1 and UL2.

The common source line CSL, the back gate line BGL, the first and second gate lower lines LL1 and LL2, word lines WL, and the first and second gate upper lines UL1 and UL2 may be electrically connected to the decoder circuit 1110 through first connection interconnections 1115 extending from the first structure 1100F to the second structure 1100S.

The bit lines BL may be electrically connected to the page buffer 1120 through second connection interconnections 1125 extending from the first structure 1100F to the second structure 1100S. The bit lines BL may be the bit lines described above.

In the first structure 1100F, the decoder circuit 1110 and the page buffer 1120 may execute a control operation on at least one selected memory cell transistor MCT among the plurality of memory cell transistors MCT. The decoder circuit 1110 and the page buffer 1120 may be controlled by a logic circuit 1130.

The semiconductor device 1100 may further include an input/output pad 1101. The semiconductor device 1100 may communicate with the controller 1200 through the input/output pad 1101 that is electrically connected to the logic circuit 1130. The input/output pad 1101 may be electrically connected to the logic circuit 1130 through an input/output connection interconnection 1135 extending from the first structure 1100F to the second structure 1100S. Accordingly, the controller 1200 is electrically connected to the semiconductor device 1100 through the input/output pad 1101 and may control the semiconductor device 1100.

The controller 1200 may include a processor 1210, a NAND controller 1120, and a host interface 1230. In some example embodiments, the data storage system 1000 may include a plurality of semiconductor devices 1100, and for example, the controller 1200 may control the plurality of semiconductor devices 1100.

The processor 1210 may control the overall operation of the data storage system 1000, including the controller 1200. The processor 1210 may operate according to desired (and/or alternatively predetermined) firmware and may control the NAND controller 1220 to access the semiconductor device 1100. The NAND controller 1220 may include a NAND interface 1221 that processes communication with the semiconductor device 1100. Through the NAND interface 1221, a control command for controlling the semiconductor device 1100, data to be written to the memory cell transistors (MCT) of the semiconductor device 1100, and data to be read from the memory cell transistors (MCT) may be transmitted. The host interface 1230 may provide a communication function between the data storage system 1000 and an external host. When a control command is received from an external host through the host interface 1230, the processor 1210 may control the semiconductor device 1100 in response to the control command.

FIG. 13 is a perspective view schematically illustrating a data storage system including a semiconductor device according to some example embodiments.

Referring to FIG. 13, a data storage system 2000 according to an some example embodiments may include a main board 2001, a controller 2002 mounted on the main board 2001, one or more semiconductor packages 2003, and DRAM 2004. The semiconductor package 2003 and the DRAM 2004 may be connected to the controller 2002 through interconnection patterns 2005 formed on the main board 2001.

The main board 2001 may include a connector 2006 including a plurality of pins coupled to an external host. The number and arrangement of the plurality of pins in the connector 2006 may vary depending on the communication interface between the data storage system 2000 and the external host. In some example embodiments, the data storage system 2000 may communicate with an external host through any one of the following interfaces: Universal Serial Bus (USB), Peripheral Component Interconnect Express (PCI-Express), Serial Advanced Technology Attachment (SATA), and M-Phy for Universal Flash Storage (UFS). In some example embodiments, the data storage system 2000 may operate with power supplied from an external host through the connector 2006. The data storage system 2000 may further include a Power Management Integrated Circuit (PMIC) that distributes power supplied from the external host to the controller 2002 and the semiconductor package 2003.

The controller 2002 may write data to the semiconductor package 2003 or read data from the semiconductor package 2003, and may improve the operating speed of the data storage system 2000.

The DRAM 2004 may be a buffer memory to alleviate the speed difference between the semiconductor package 2003, which is a data storage space, and an external host. The DRAM 2004 included in the data storage system 2000 may also operate as a type of cache memory, and in a control operation for the semiconductor package 2003, a space for temporarily storing data may be provided. When the data storage system 2000 includes the DRAM 2004, the controller 2002 may further include a DRAM controller for controlling the DRAM 2004 and to a NAND controller for controlling the semiconductor package 2003.

The semiconductor package 2003 may include first and second semiconductor packages 2003a and 2003b that are spaced apart from each other. The first and second semiconductor packages 2003a and 2003b may each include a plurality of semiconductor chips 2200. Each of the semiconductor chips 1200 may include a semiconductor device according to any of some example embodiments described above with reference to FIGS. 1 to 10.

Each of the first and second semiconductor packages 2003a and 2003b may include a package substrate 2100, semiconductor chips 2200 on a package substrate 2100, adhesive layers 2300 disposed on the lower surface of each of the semiconductor chips 2200, a connection structure 2400 that electrically connects the semiconductor chips 2200 and the package substrate 2100, and a molding layer 2500 covering the semiconductor chips 2200 and the connection structure 2400 on the package substrate 2100.

The package substrate 2100 may be a printed circuit board including upper package pads 2130. Each of the semiconductor chips 2200 may include an input/output pad 2210.

In some example embodiments, the connection structure 2400 may be a bonding wire that electrically connects the input/output pad 2210 and the package top pads 2130. Accordingly, in each of the first and second semiconductor packages 2003a and 2003b, the semiconductor chips 2200 may be electrically connected to each other using a bonding wire method, and may be electrically connected to the package upper pads 2130 of the package substrate 2100. According to some example embodiments, in each of the first and second semiconductor packages 2003a and 2003b, the semiconductor chips 2200 may be electrically connected to each other by a connection structure including a through electrode (Through Silicon Via, TSV) instead of the bonding wire type connection structure 2400.

In some example embodiments, the controller 2002 and the semiconductor chips 2200 may be included in one package. For example, the controller 2002 and the semiconductor chips 2200 are mounted on a separate interposer board different from the main board 2001, and the controller 2002 and the semiconductor chips 2200 may be connected to each other through interconnection formed on the interposer substrate.

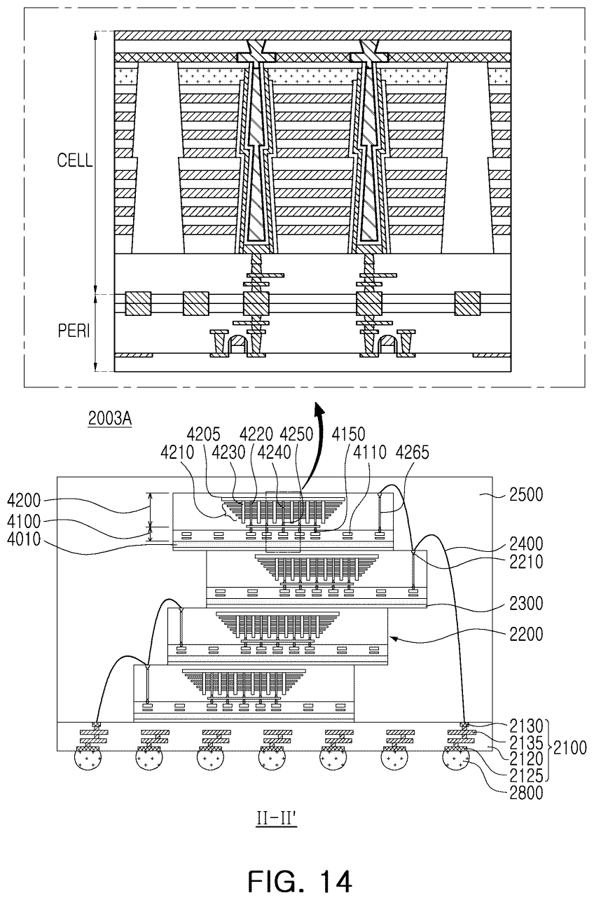

FIG. 14 is a cross-sectional view schematically illustrating a semiconductor package according to some example embodiments. FIG. 14 illustrates some example embodiments of the semiconductor package 2003 of FIG. 13 and conceptually illustrates the area of the semiconductor package 2003 in FIG. 13, taken along line II-II′.

Referring to FIGS. 13 and 14, in the semiconductor package 2003, the package substrate 2100 may be a printed circuit board. The package substrate 2100 may include a package substrate body 2120, package upper pads 2130 disposed on the upper surface of the package substrate body 2120, and lower pads 2125 disposed on or exposed through the lower surface of the package substrate body 2120, and internal interconnections 2135 electrically connecting the upper pads 2130 and the lower pads 2125 inside the package substrate body 2120. The upper pads 2130 may be electrically connected to the connection structures 2400. The lower pads 2125 may be connected to the interconnection patterns 2005 of the main board 2001 of the data storage system 2000 through conductive connectors 2800.

Each of the semiconductor chips 2200 may include a semiconductor substrate 4010 and a first structure 4100 and a second structure 4200 that are sequentially stacked on the semiconductor substrate 4010. The first structure 4100 may include a peripheral circuit area including peripheral wires 4110. The second structure 4200 may include a common source line 4205, a stack structure 4210 on the common source line 4205, memory channel structures 4220 and separation structures 4230 penetrating through the stack structure 4210, bit lines 4240 electrically connected to the memory channel structures 4220, and gate contact plugs 4150 electrically connected to the word lines WL of the stack structure 4220. The first structure 4100 may include the first structure 1100F of FIG. 12, and the second structure 4200 may include the second structure 1100S of FIG. 12.

Each of the semiconductor chips 2200 may include a through interconnection 4265 that is electrically connected to the peripheral interconnections 4110 of the first structure 4100 and extends into the second structure 4200. The through interconnection 4265 may penetrate the stack structure 4210 and may be further disposed outside the stack structure 4210.

Each of the semiconductor chips 2200 may further include an input/output connection interconnection 4265 that is electrically connected to the peripheral wires 4110 of the first structure 4100 and extends into the second structure 4200, and an input/output pad 2210 electrically connected to the input/output connection interconnection 4265.

In FIG. 14, the enlarged portion indicated including portions of the first structure 4100 and the second structure 4200 of the semiconductor chips 2200 of FIG. 14 may be modified to include the same cross-sectional structure as in FIG. 3. Therefore, each of the semiconductor chips 2200 may also include a semiconductor device 100 according to any one of some example embodiments described above with reference to FIGS. 6 to 10, instead of the semiconductor device according to the example embodiments of FIG. 3.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc.

As set forth above, according to some example embodiments, an information storage layer using a ferroelectric layer capable of storing information using a polarization state may be included, and the polarization state of an unselected cell may be maintained by applying a back gate voltage through a back gate electrode. Accordingly, when a program voltage is applied to a neighboring cell, the electric field effect caused by a continuous channel or continuous dielectric layers may be significantly reduced.

A back gate contact connected to the back gate electrode is disposed above the vertical structure, and the bit line contact is disposed below the vertical structure, and thus the area of the back gate contact may be secured.

A pad of an enlarged area may be connected between the back gate electrode and the back gate contact to limit and/or prevent misalignment between the back gate electrode and the back gate contact, and the freedom of size of the back gate contact may be guaranteed, thereby reducing process difficulty.

An insulating layer may be formed above the common source layer, thereby forming a pad of the back gate contact, the channel layer, and the common source layer to be electrically separated from each other, and thereby limiting and/or preventing short circuit between the channel layer and the common source layer.

While some example embodiments have been illustrated and described above, it will be apparent to those skilled in the art that modifications and variations could be made without departing from the scope of the inventive concepts as defined by the appended claims.

What is claimed is:

1. A semiconductor device comprising:
a stack structure including interlayer insulating layers and gate electrodes alternately stacked in a vertical direction;
a plate layer on the stack structure;
vertical structures respectively comprising
a back gate electrode penetrating through the stack structure and the plate layer in the vertical direction,
a channel layer between the back gate electrode and the gate electrodes, and
a gate dielectric structure including a ferroelectric layer between the channel layer and the gate electrodes;
a first horizontal insulating layer on upper surfaces of the plate layer and the channel layer;
a second horizontal insulating layer on the first horizontal insulating layer, the second horizontal insulating layer including a material different than a material of the first horizontal insulating layer; and
back gate contacts respectively on the vertical structures, the back gate contacts being electrically connected to respective ones of the back gate electrodes of the vertical structures, and the back gate contacts including a pad region in the second horizontal insulating layer and a via region protruding upwardly from the pad region.

2. The semiconductor device of claim 1, wherein the vertical structures respectively further include a first insulating layer between the back gate electrode and the channel layer, and
wherein the channel layer and the back gate contacts are electrically separated by the first insulating layer and the first horizontal insulating layer.

3. The semiconductor device of claim 2, wherein an upper surface of the channel layer and an upper surface of the plate layer are coplanar, and an upper surface of the first insulating layer is at a higher level than the upper surface of the channel layer.

4. The semiconductor device of claim 2, wherein the gate dielectric structure further includes
a second insulating layer between the ferroelectric layer and the gate electrodes, and
an interface insulating layer between the ferroelectric layer and the channel layer, and
wherein the first insulating layer, the second insulating layer, and the interface insulating layer include a same material.

5. The semiconductor device of claim 1, wherein an upper surface of the back gate electrode is at a lower level than an upper surface of the first horizontal insulating layer.

6. The semiconductor device of claim 1, wherein the back gate contacts further include a protrusion protruding downward from the pad region toward an upper surface of the respective ones of the back gate electrodes and contacting the respective ones of the back gate electrodes.

7. The semiconductor device of claim 6, wherein the back gate contacts include a barrier film on a side surface and a lower surface of the back gate contacts, and a conductive material filling the barrier film.

8. The semiconductor device of claim 7, wherein the barrier film is at an interface between the protrusion and the upper surface of the respective ones of the back gate electrodes.

9. The semiconductor device of claim 1, wherein a width of an upper surface of the vertical structures is smaller than a width of the pad region of the back gate contacts.

10. The semiconductor device of claim 1, wherein a width of an upper surface of the vertical structures is smaller than a width of a lower surface of the vertical structures, and
a width of an upper surface of the via region of the back gate contacts is greater than a width of a lower surface of the via region of the back gate contacts.

11. The semiconductor device of claim 10, wherein a width of the pad region of the back gate contacts is equal to or smaller than the width of the lower surface of the vertical structures.

12. The semiconductor device of claim 10, wherein a center line of the width of the lower surface of the vertical structures is coaxial with a center line of the width of the lower surface of the via region of the back gate contacts connected to the vertical structures.

13. The semiconductor device of claim 10, wherein a center line of the width of the lower surface of the via region is offset with respect to a center line of the width of the lower surface of the vertical structures connected to the back gate contacts.

14. The semiconductor device of claim 1, further comprising a third horizontal insulating layer between the first horizontal insulating layer and the second horizontal insulating layer,
wherein the third horizontal insulating layer has a thickness greater than a thickness of the first horizontal insulating layer.

15. The semiconductor device of claim 14, wherein the second horizontal insulating layer includes a material different than a material of the first horizontal insulating layer and the third horizontal insulating layer.

16. The semiconductor device of claim 1, wherein the gate dielectric structure further includes a charge trap layer between the ferroelectric layer and the gate electrodes.

17. A semiconductor device comprising:
a first semiconductor structure including a first substrate, circuits on the first substrate, a lower interconnection structure electrically connected to the circuits, and a lower bonding structure connected to the lower interconnection structure; and
a second semiconductor structure including
a second substrate on the first semiconductor structure,
a stack structure including interlayer insulating layers and gate electrodes stacked in a vertical direction perpendicular to a lower surface of the second substrate,
vertical structures respectively including a back gate electrode penetrating through the stack structure and the second substrate in the vertical direction, the vertical structures including a channel layer between the back gate electrode and the gate electrodes,
an upper interconnection structure below the vertical structures,
an upper bonding structure connected to the upper interconnection structure and bonded to the lower bonding structure,
a first horizontal insulating layer on the second substrate and an upper surface of the channel layer,
a second horizontal insulating layer on the first horizontal insulating layer and including a material different than a material of the first horizontal insulating layer; and
back gate contacts respectively on the vertical structures, the back gate contacts being electrically connected to respective ones of the back gate electrodes of the vertical structures, and the back gate contacts including a pad region in the second horizontal insulating layer and a via region protruding upwardly from the pad region.

18. The semiconductor device of claim 17, wherein the vertical structures respectively further include a gate dielectric structure including a ferroelectric layer between the channel layer and the gate electrodes.

19. The semiconductor device of claim 17, wherein a width of an upper surface of the vertical structures is smaller than a width of the pad region of the back gate contacts.

20. A data storage system comprising:
a semiconductor device including an input/output pad; and
a controller electrically connected to the semiconductor device through the input/output pad and controlling the semiconductor device,
wherein the semiconductor device comprises
a stack structure including interlayer insulating layers and gate electrodes stacked in a vertical direction,
a plate layer on the stack structure,
vertical structures respectively including
a back gate electrode penetrating through the stack structure and the plate layer in the vertical direction,
a channel layer between the back gate electrode and the gate electrodes, and
a gate dielectric structure including a ferroelectric layer between the channel layer and the gate electrodes,
a first horizontal insulating layer on upper surfaces of the plate layer and the channel layer,
a second horizontal insulating layer on the first horizontal insulating layer, the second horizontal insulating layer including a material different than a material of the first horizontal insulating layer, and
back gate contacts respectively on the vertical structures, the back gate contacts being electrically connected to respective ones of the back gate electrodes of the vertical structures, and
the back gate contacts including a pad region in the second horizontal insulating layer, a via region protruding upwardly from the pad region, and a protrusion protruding downward from the pad region toward an upper surface of the respective ones of the back gate electrodes and contacting the respective ones of the back gate electrodes.
